(19) United States
(12) Patent Application Publication
(10) Pub. No.: US 2025/0079353 A1
(43) Pub. Date: Mar. 6, 2025

(54) POWER CONVERTER, EMBEDDED INTEGRATED DEVICE UNIT, HIGH-HEAT-DISSIPATION HIGH-FREQUENCY POWER MODULE AND MANUFACTURING METHOD THEREFOR

(71) Applicant: SHANGHAI METAPWR ELECTRONICS CO., LTD, Shanghai (CN)

(72) Inventor: Jianhong ZENG, Shanghai (CN)

(73) Assignee: SHANGHAI METAPWR ELECTRONICS CO., LTD, Shanghai (CN)

(21) Appl. No.: 18/951,620

(22) Filed: Nov. 18, 2024

Related U.S. Application Data
(63) Continuation of application No. PCT/CN2023/094620, filed on May 16, 2023.

(30) Foreign Application Priority Data
May 19, 2022 (CN) 202210544881.8

(51) Int. Cl. H01L 23/66; H01L 21/50; H01L 23/373; H01L 23/473; H01L 23/538; H01L 25/16

(52) U.S. Cl. CPC H01L 23/66; H01L 21/50; H01L 23/3735; H01L 23/473; H01L 23/5385; H01L 25/16; H10D 1/68

(57) ABSTRACT

A high-heat-dissipation high-frequency power module including an embedded circuit board, at least two semiconductor power devices, at least one high-frequency capacitor, and an insulating heat-conducting material is provided. Power electrodes of the at least two semiconductor power devices are connected in series to form at least one power conversion bridge arm. A ratio of the area of the overlapping projections of the power electrodes' wiring of the semiconductor power devices led out from the surface of the embedded circuit board, and the area of the semiconductor power devices is 60% or more. A power conversion bridge arm is connected in parallel to the high-frequency capacitor nearby so as to realize a low-loop inductance interconnection.

### CROSS-REFERENCE TO RELATED APPLICATIONS

This application is a continuation of international application of PCT patent application PCT/CN2023/094620, filed on May 16, 2023, which claims the priority benefit of China application no. 202210544881.8 filed on May 19, 2022. The entirety of the above-mentioned patent application is hereby incorporated by reference herein and made a part of this specification.

### TECHNICAL FIELD

The invention relates to the field of semiconductor technology, and in particular relates to a power converter, an embedded integrated device unit, a high-heat-dissipation high-frequency power module and a manufacturing method therefor.

### DESCRIPTION OF RELATED ART

In the field of electric energy power conversion, the contribution to energy conservation and emission reduction comes from two points: high efficiency to reduce direct energy consumption and high power-density to reduce material use so as to reduce indirect energy consumption. High power-density is achieved at high frequencies, but high frequency and high efficiency tend to be contradictory. Therefore, in order to achieve high efficiency at high frequency, the loop inductance needs to be greatly reduced, and as the bridge arm loop inductance Lloop in FIG. 1A needs to descend along with the increase of the frequency and the like.

In addition, the semiconductor bridge arm is a basic unit and a core of the power converter, usually at least two semiconductor power switches Q1 and Q2 are connected in series and then are connected with a direct-current voltage in parallel, and in order to reduce the inductance of the loop, the bridge arm is connected nearby with a decoupling capacitor Cbus in parallel at the direct-current voltage. In this way, in the switching process, due to the sudden change of di/dt current, the voltage peak generated on the Lloop is limited, so that normal work is ensured.

In a high-power converter occasion, the power density is improved, how to process heat dissipation, especially heat dissipation of a semiconductor power device, the more heat can be processed, and the power density can be improved under larger power. Therefore, the improvement of the high heat dissipation capability is the representative direction of the technical precision in the field, as shown in FIG. 1B, which is a typical representation of double-sided heat dissipation in the prior art. It is to be noted that the technical features disclosed by the application are illustrated by taking the double-sided heat dissipation embodiment as an example, but the technical features disclosed by the application can be applied to a single-sided heat dissipation embodiment; and generally, double-sided heat dissipation is applied to the application with extremely high requirements on the heat dissipation density, so that the liquid cooling heat dissipation device is often adopted.

In the prior art, a pin copper frame is welded on an insulating heat conduction layer (usually a ceramic substrate and hereinafter referred to as DBC), and then a semiconductor power device (such as an MOSFET, an IGBT, a SIC and a GaN) is welded on the copper frame, and then the electrode is led out to the pin through a bonding wire. In order to leave enough space for the height of the bonding wire, a thermal conducting pad (usually a copper alloy) is welded to the power electrode on the upper surface of the semiconductor power device, and then an insulating heat conducting layer is welded to the upper surface of the thermal conducting pad. Finally, the fins of the liquid cooling heat dissipation component are welded on the upper surface and the lower surface of the combination body, so that a good double-sided heat dissipation effect is achieved.

However, due to the intervention of the thermal conduction pad and the poor precision of the copper frame wiring, the bridge arm loop is relatively large, and is usually difficult to be less than 10 nH, so that the rise of current and frequency is limited.

Due to the fact that the thermal conduction pad is placed above the semiconductor power device through the welding process, in order to guarantee the tolerance, the area of the thermal conduction pad is generally obviously smaller than the area of the semiconductor power device, and due to the fact that the pad is thick and usually at least 1 mm or above, the thermal resistance of the pad cannot be ignored, the thermal resistance reduction of upward heat dissipation of the semiconductor power device is limited, and therefore an expected high heat dissipation effect cannot be achieved.

In conclusion, the existing high-heat-dissipation technology is insufficient in high-frequency performance or thermal resistance. Therefore, how to simultaneously realize high-frequency high-current characteristics and nearly ideal high-heat-dissipation capability is an urgent problem to be solved.

### SUMMARY

In view of this, one of the objectives of the present application is to provide a high-heat-dissipation high-frequency power module comprises embedded circuit board, at least two semiconductor power devices, at least one high-frequency capacitor and an insulating heat-conducting carrier plate.
the embedded circuit board comprises an upper surface and a lower surface which are opposite to each other, an inner layer, at least one electrical connection path and at least one high-density and high-thermal-conductivity conductive path, wherein the upper surface comprises a first wiring layer and the lower surface comprises a second wiring layer;
the at least two semiconductor power devices are arranged in the embedded circuit board, each semiconductor power device comprises a power electrode, power electrodes of the at least two semiconductor devices are electrically connected with the wiring layer through the electrical connection paths, and power electrodes of the at least two semiconductor devices are electrically connected to form at least one power conversion bridge arm in the high-heat-dissipation high frequency power module;
the semiconductor power device comprises two opposite device surfaces, the surface of the at least one device is connected with the wiring layer through the high-density high-thermal-conductivity conductive path, and the wiring layer connected with the high-density high-thermal-conductivity conductive path can serve as a heat dissipation surface;
the high-frequency capacitor is arranged adjacent to the power conversion bridge arm and is electrically connected with the power conversion bridge arm in parallel so as to realize low-loop electrical interconnection;
the insulating heat-conducting carrier plate comprises a heat-conducting upper surface and a heat-conducting lower surface which are opposite to each other, and the heat-conducting lower surface is attached to the heat-dissipating surface; the insulating heat-conduction carrier plate covers the area corresponding with the power conversion bridge arm;
the connecting direction of at least two semiconductor power devices is a first direction, and the direction perpendicular to the first direction is a second direction in the same horizontal plane;
the high-frequency capacitor is disposed in a second direction;
the at least two semiconductor power devices, the first wiring layer and the second wiring layer form a conductive path in a “∞” shape on the cross section in the first direction; the current flowing in the conductive path from a Vbus+ terminal to a Vbus− terminal; the Vbus+ terminal and the Vbus− terminal are led out in the second direction in stacked mode, to realize low-loop electrical interconnection.

Preferably, the high-heat-dissipation high-frequency power module further comprises a packaging body and a heat dissipation component, wherein the packaging body at least covers a part of the embedded circuit board and the insulating heat-conducting carrier plate, at least one end of the embedded circuit board directly or indirectly extends to the outside of the projection of the insulating heat-conducting carrier plate on the embedded circuit board, and the heat-conducting upper surface of the insulating heat-conducting carrier plate is exposed; the heat dissipation component is arranged on the surface of the insulating heat-conducting carrier plate in an attached mode.

Preferably, the package body is formed by encapsulating a pouring sealant;
the heat dissipation component comprises an upper heat dissipation component and a lower heat dissipation component, and the upper heat dissipation component and the lower heat dissipation component are located on the upper side and the lower side of the embedded circuit board respectively; The upper heat dissipation component and the lower heat dissipation component are hermetically connected to one side of the embedded circuit board to form a cavity structure, and the cavity structure is filled with liquid pouring sealant.

Preferably, the packaging body is formed by a plastic packaging material;
the gap between the insulating heat-conducting carrier plate and the wiring layer is pre-filled with a dispensing adhesive, and the side wall of the insulating heat-conducting carrier plate is provided with a step-shaped structure.

Preferably, the high-heat-dissipation high-frequency power module further comprises a system mainboard, and the embedded circuit board is implanted in a system mainboard and is connected with the system mainboard; one side of the embedded circuit board is flush with one side of the system mainboard, and the embedded circuit board and the system mainboard are electrically connected through a through-hole electrical connection structure and/or a surface wiring layer.

Preferably, the at least two semiconductor power devices in one power conversion bridge arm are arranged in a same embedded circuit board.

A high-heat-dissipation high-frequency power module comprises at least one embedded circuit board, at least two semiconductor power devices, at least one high-frequency capacitor and an insulating heat-conducting carrier plate;
the at least one embedded circuit board comprises an upper surface and a lower surface which are opposite to each other, an inner layer, at least one electrical connection path and at least one high-density and high-thermal-conductivity conductive path, wherein the upper surface comprises a first wiring layer and the lower surface comprises a second wiring layer;
the at least two semiconductor power devices are arranged in the embedded circuit board, each semiconductor power device comprises a power electrode, power electrodes of the at least two semiconductor devices are electrically connected with the wiring layer through the electrical connection paths, and power electrodes of the at least two semiconductor devices are electrically connected to form at least one power conversion bridge arm in the high-heat-dissipation high frequency power module;
the semiconductor power device comprises two opposite device surfaces, the surface of the at least one device is connected with the wiring layer through the high-density high-thermal-conductivity conductive path, and the wiring layer connected with the high-density high-thermal-conductivity conductive path can serve as a heat dissipation surface;
the high-frequency capacitor is arranged adjacent to the power conversion bridge arm and is electrically connected with the power conversion bridge arm in parallel so as to realize low-loop electrical interconnection;
the insulating heat-conducting carrier plate comprises a heat-conducting upper surface and a heat-conducting lower surface which are opposite to each other, and the heat-conducting lower surface is attached to the heat-dissipating surface; the insulating heat-conducting carrier plate covers the area corresponding to the power conversion bridge arm; the high frequency capacitor is arranged in the area not covered by the insulating heat-conducting carrier plate.

Preferably, the high frequency capacitors are arranged along a side of the heat-conducting carrier plate in a row.

Preferably, the high-heat-dissipation high-frequency power module further comprises a packaging body and a heat dissipation component, wherein the packaging body at least covers a part of the embedded circuit board and the insulating heat-conducting carrier plate, at least one end of the embedded circuit board directly or indirectly extends to the outside of the projection of the insulating heat-conducting carrier plate on the embedded circuit board, and the heat-conducting upper surface of the insulating heat-conducting carrier plate is exposed; the heat dissipation component is arranged on the surface of the insulating heat-conducting carrier plate in an attached mode.

Preferably, the heat dissipation component comprises an upper heat dissipation component and a lower heat dissipation component, and the upper heat dissipation component and the lower heat dissipation component are located on the upper side and the lower side of the embedded circuit board respectively.

Preferably, the package body is formed by encapsulating a pouring sealant; the upper heat dissipation component and the lower heat dissipation component are hermetically connected to one side of the embedded circuit board to form a cavity structure, and the cavity structure is filled with liquid pouring sealant, and the liquid pouring sealant is cured in the cavity.

Preferably, the at least one embedded circuit board extends out of the cavity structure in at least two directions.

Preferably, the high-heat-dissipation high-frequency power module further comprises a liquid cooling cover plate and a sealing piece, the liquid cooling cover plate and the sealing piece are arranged outside the heat dissipation component, and the sealing piece is arranged at the joint of the liquid cooling cover plate and the heat dissipation component.

Preferably, the high-heat-dissipation high-frequency power module further comprises a shell, one end of the shell is open, the other end of the shell is closed, an opening for containing a heat dissipation component is formed in the middle of the shell, the shell and the heat dissipation component are connected in a sealed mode to form a cavity structure, and the cavity structure is filled with liquid pouring sealant.

Preferably, the high-heat-dissipation high-frequency power module further comprises a thin-wall structure, the thin-wall structure is arranged between the shell and the heat dissipation component, and the thin-wall structure is used for compensating for assembly tolerance.

Preferably, the high-heat-dissipation high-frequency power module further comprises a sealing baffle, the sealing baffle is arranged on the two sides of the heat dissipation component, a glue injection opening is formed in one sealing baffle, the sealing baffle and the heat dissipation component are connected in a sealed mode to form a cavity structure, and the cavity structure is filled with liquid pouring sealant.

Preferably, the sealing baffle is a special-shaped baffle, and a larger cavity structure is formed by enveloping.

Preferably, the packaging body is formed by packaging a plastic packaging material; the gap between the insulating heat-conducting carrier plate and the wiring layer is pre-filled with a dispensing adhesive, and the side wall of the insulating heat-conducting carrier plate is provided with a step-shaped structure.

Preferably, the high-heat-dissipation high-frequency power module further comprises a system mainboard, and the embedded circuit board is electrically connected with the system mainboard.

Preferably, the embedded circuit board is implanted to or is welded on a system mainboard; one side of the embedded circuit board is flush with one side of the system mainboard, and the embedded circuit board and the system mainboard are electrically connected through a through-hole electrical connection structure and/or a surface wiring layer.

Preferably, the high-frequency capacitor is arranged on a system mainboard, and the high-frequency capacitor is close to the embedded circuit board; the high-heat-dissipation high-frequency power further comprises a heat dissipation component, the heat dissipation component is attached to the heat conduction upper surface of the insulating heat-conducting carrier plate, sealing baffles are further arranged on the two sides of the heat dissipation component, the sealing baffle and the heat dissipation component are connected in a sealed mode to form a cavity structure, and the cavity structure is filled with liquid pouring sealant.

Preferably, a liquid cooling cover plate is arranged outside the heat dissipation component, and a sealing piece is arranged at the joint of the liquid cooling cover plate and the heat dissipation component.

Preferably, the liquid cooling cover plate extends out of the side edge of the heat dissipation component to form a liquid flow channel, and a magnetic element is attached to the inner side of the liquid flow channel;
the outer side of the liquid flow channel seals the magnetic element by providing a sealing baffle.

Preferably, a sealing baffle between the liquid flow channel and the heat dissipation component is removed, so that the liquid flow channel, the heat dissipation component and the sealing baffle form a cavity structure.

Preferably, one or more of a driving element, a low-frequency large-size element, a control unit and a magnetic element are arranged on a system mainboard in the cavity structure.

Preferably, in the same cavity structure, a plurality of embedded circuit boards are arranged on the system mainboard, and one or more of a driving element, a low-frequency large-size element, a control unit and a magnetic element are arranged on a system mainboard near each embedded circuit board to form a circuit unit; and the plurality of circuit units are integrated on a client mainboard.

Preferably, a vertically penetrating through-opening is formed in the embedded circuit board, and the high-frequency capacitor is arranged in the through-opening.

Preferably, the at least two semiconductor power devices in one power conversion bridge arm are arranged in a same embedded circuit board.

Preferably, a manufacturing method of the high-heat-dissipation high-frequency power module, the manufacturing method comprises the following steps:
S1: arranging a temporary protection layer on one surface of an embedded circuit board;
S2: the embedded circuit board is arranged in the system mainboard, and the surface of the embedded circuit board which is not provided with the temporary protection layer is flush with one surface of the system mainboard;
S3: completing the arrangement of the through-hole electrical connection structure and the surface wiring layer;
S4: cutting off the periphery of the embedded circuit board needing to be exposed, and exposing the temporary protection layer;
S5: removing the temporary protective layer.

Preferably, a manufacturing method of the high-heat-dissipation high-frequency power module, the manufacturing method comprises the following steps:
S1: respectively arranging a temporary protection layer on the upper surface and the lower surface of the embedded circuit board;
S2: arranging the embedded circuit board in the system mainboard;
S3: completing the arrangement of the through-hole electrical connection structure;
S4: cutting off the periphery of the embedded circuit board needing to be exposed, and exposing the temporary protection layer;
S5: removing the temporary protective layer.

A high-heat-dissipation high-frequency power module comprises at least one embedded circuit board, at least two semiconductor power devices, at least one high-frequency capacitor, an insulating heat-conducting carrier plate and a double-side-heat-dissipation half-sealed heat dissipation cover;
the embedded circuit board comprises an upper surface and a lower surface which are opposite to each other, an inner layer, at least one electrical connection path and at least one high-density and high-thermal-conductivity conductive path, wherein the upper surface comprises a first wiring layer and the lower surface comprises a second wiring layer;
the at least two semiconductor power devices are arranged in the embedded circuit board, each semiconductor power device comprises a power electrode, power electrodes of the at least two semiconductor devices are electrically connected with the wiring layer through the electrical connection paths, and power electrodes of the at least two semiconductor devices are electrically connected to form at least one power conversion bridge arm in the high-heat-dissipation high frequency power module;
the semiconductor power device comprises two opposite device surfaces, the surface of the at least one device is connected with the wiring layer through the high-density high-thermal-conductivity conductive path, and the wiring layer connected with the high-density high-thermal-conductivity conductive path can serve as a heat dissipation surface;
the high-frequency capacitor is arranged adjacent to the power conversion bridge arm and is electrically connected with the power conversion bridge arm in parallel so as to realize low-loop electrical interconnection;
the insulating heat-conducting carrier plate comprises a heat-conducting upper surface and a heat-conducting lower surface which are opposite to each other, and the heat-conducting lower surface is attached to the heat-dissipating surface; the insulating heat-conducting carrier plate covers the area corresponding to the power conversion bridge arm.

The double-side-heat-dissipation half-sealed heat dissipation cover comprises an upper heat dissipation component and a lower heat dissipation component, the upper heat dissipation component and the lower heat dissipation component are arranged on the upper side or the lower side of the at least one embedded circuit board respectively; the upper heat dissipation component and the lower heat dissipation component are hermetically connected to one side of the embedded circuit board to form a cavity structure, and the cavity structure is filled with liquid pouring sealant.

Preferably, the connecting direction of at least two semiconductor power devices is a first direction, and the direction perpendicular to the first direction is a second direction in the same horizontal plane;
the high-frequency capacitor is disposed in a second direction.

Preferably, the at least one embedded circuit board extends out of the cavity structure in at least two directions.

Preferably, the high-heat-dissipation high-frequency power module further comprises a liquid cooling cover plate and a sealing piece, the liquid cooling cover plate and the sealing piece are arranged outside the heat dissipation component, and the sealing piece is arranged at the joint of the liquid cooling cover plate and the heat dissipation component.

Preferably, the high-heat-dissipation high-frequency power module further comprises a shell, one end of the shell is open, the other end of the shell is closed, an opening for containing a heat dissipation component is formed in the middle of the shell, the shell and the heat dissipation component are connected in a sealed mode to form a cavity structure, and the cavity structure is filled with liquid pouring sealant.

Preferably, the high-heat-dissipation high-frequency power module further comprises a thin-wall structure, the thin-wall structure is arranged between the shell and the heat dissipation component, and the thin-wall structure is used for compensating for assembly tolerance.

Preferably, the high-heat-dissipation high-frequency power module further comprises a sealing baffle, the sealing baffle is arranged on the two sides of the heat dissipation component, a glue injection opening is formed in one sealing baffle, the sealing baffle and the heat dissipation component are connected in a sealed mode to form a cavity structure, and the cavity structure is filled with liquid pouring sealant.

Preferably, the sealing baffle is a special-shaped baffle, and a larger cavity structure is formed by enveloping.

Preferably, the high-heat-dissipation high-frequency power module further comprises at least two insulating heat-conducting carrier plate, the at least two insulating heat-conducting carrier plates are respectively attached to the upper heat dissipation surface and the lower heat dissipation surface.

Preferably, the at least two semiconductor power devices in one power conversion bridge arm are arranged in a same embedded circuit board.

Compared with the prior art, the application has the following beneficial effects:

(1) Due to the excellent heat dissipation treatment, each 10 square millimeter semiconductor power device can be optimally smaller than 0.2 degree/watt from a device to a wiring layer, the thermal resistance of the wiring layer to the outer side of the insulating heat conduction material is smaller than 0.8 degree/watt, and the total single-sided thermal resistance is smaller than 1 degree/watt. The double-sided heat dissipation is less than 0.5 degrees/watt. Calculating the temperature difference of 50 DEG C, allowing each 10 square millimeter semiconductor power device to achieve 100 W calorific value, and meeting the high power demand for a long time at present and in the future.

(2) Due to the excellent loop processing of the application, the bridge arm loop inductance composed of two 10 square millimeter semiconductor power devices has an opportunity less than 2 nH or even less than 1 nH, is suitable for frequency MHz requirements, and is far higher than the mainstream frequency lower than 100 kHz.

### BRIEF DESCRIPTION OF THE DRAWINGS

FIG. 1A is a circuit diagram of a semiconductor bridge arm in the prior art.

FIG. 1B and FIG. 1C are schematic diagrams of a high heat dissipation module in the prior art.

FIG. 2A is a schematic structural diagram of a high-heat-dissipation high-frequency power module according to an embodiment of the present application.

FIG. 2B is a schematic diagram of a current when a high-heat-dissipation high-frequency power module adopts a vertical device according to an embodiment of the present application.

FIG. 3A is a schematic diagram of a conductive material bonding layer of a high-heat-dissipation high-frequency power module according to an embodiment of the present application.

FIG. 3B is a schematic diagram of an inner-layer redistribution layer of a high-heat-dissipation high-frequency power module according to an embodiment of the present application.

FIG. 4A is a schematic diagram of a current when a high-heat-dissipation high-frequency power module adopts a planar device according to an embodiment of the present application.

FIG. 4B is a schematic diagram of an insulating material bonding layer of a high-heat-dissipation high-frequency power module according to an embodiment of the present application.

FIG. 5A and FIG. 5B are schematic diagrams of setting a high-frequency capacitor of a high-heat-dissipation high-frequency power module in a second direction according to an embodiment of the present application.

FIG. 5C is a schematic diagram of an interconnection metal layer of a high-heat-dissipation high-frequency power module according to an embodiment of the present application.

FIG. 6A to FIG. 6C are schematic diagrams of different arrangement positions of a high-frequency capacitor of a high-heat-dissipation high-frequency power module according to an embodiment of the present application.

FIG. 7A to FIG. 7D are schematic diagrams when a packaging body of a high-heat-dissipation high-frequency power module adopts liquid pouring sealant according to an embodiment of the present application.

FIG. 8A and FIG. 8B are schematic diagrams of a sealing baffle of a high-heat-dissipation high-frequency power module according to an embodiment of the present application.

FIG. 9A and FIG. 9B are schematic diagrams of pre-filling gaps between wiring layers of an insulating heat-conducting carrier plate of a high-heat-dissipation high-frequency power module according to an embodiment of the present application.

FIG. 10A and FIG. 10B are schematic diagrams of a high-heat-conductivity insulating film of a high-heat-dissipation high-frequency power module according to an embodiment of the present application.

FIG. 11A to FIG. 11D are schematic diagrams of a connection mode of an embedded circuit board and a system mainboard of a high-heat-dissipation high-frequency power module according to an embodiment of the present application.

FIG. 12A to FIG. 12D are flowcharts of a method for manufacturing the connection mode between the embedded circuit board and the system mainboard shown in FIG. 11B.

FIG. 13A to FIG. 13D are flowcharts of a method for manufacturing the connection mode between the embedded circuit board and the system mainboard shown in FIG. 11C.

FIG. 14A to FIG. 14D are schematic application diagrams of an embedded circuit board and a system mainboard of a high-heat-dissipation high-frequency power module according to an embodiment of the present application.

FIG. 15A to FIG. 15C are schematic diagrams of a package of a high-heat-dissipation high-frequency power module adopting plastic packaging according to an embodiment of the present application.

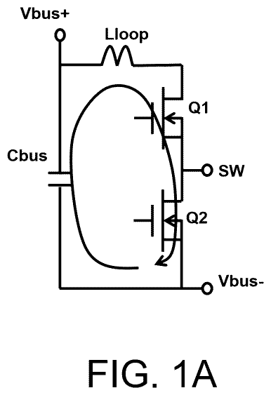

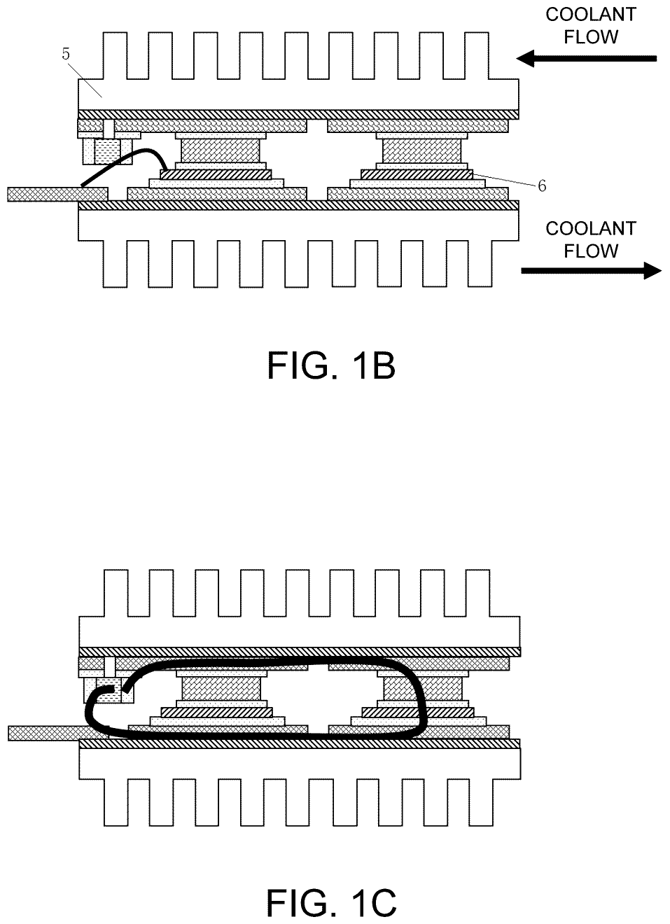

### DESCRIPTION OF THE EMBODIMENTS

The present application discloses a high-heat-dissipation high-frequency power module and a manufacturing method therefor. The module comprises: an embedded circuit board, at least one high-frequency capacitor, and an insulating heat-conducting material. Power electrodes of at least two semiconductor power devices are connected in series to form at least one power conversion bridge arm. The ratio of the area of the overlapping projections of the power electrodes' wiring of the semiconductor power devices led out from the surface of the embedded circuit board, and the area of the semiconductor power devices is 60% or more. The power conversion bridge arm is connected in parallel to the high-frequency capacitor nearby so as to realize low-loop inductance interconnection. According to the present application, high-frequency high-current characteristics can be realized, and the single-sided high heat dissipation capability and nearly ideal double-sided high heat dissipation capability are realized. Due to the excellent loop processing in the present application, the inductance of a bridge arm loop comprising two semiconductor power devices per 10 square millimeters has an opportunity to be less than 2 nH and even less than 1 nH, is suitable for the requirement of frequency MHz, and is far higher than the current mainstream frequency lower than 100 KHz.

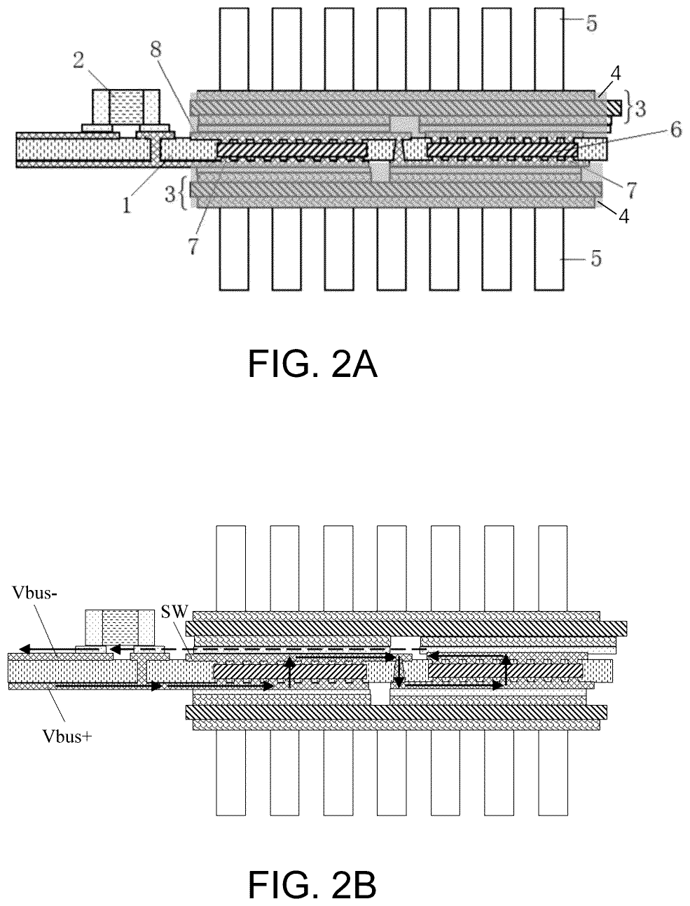

FIG. 2A to FIG. 2B show a schematic structural diagram of a high-heat-dissipation high-frequency power module according to an embodiment of the present application. The high-heat-dissipation high-frequency power module comprises:
the embedded circuit board 1 comprises an upper surface and a lower surface which are opposite to each other, an inner layer. The inner layer of the embedded circuit board 1 is provided with at least two semiconductor power devices 6, the semiconductor power devices 6 are horizontally arranged on the inner layer of the embedded circuit board 1, the power electrodes of the semiconductor power devices 6 are electrically connected to the wiring layers 8 arranged on the upper surface and/or the lower surface of the embedded circuit board 1 through electrical connection paths 7, and the power electrodes of the at least two semiconductor power devices 6 are connected in series through the wiring layers 8 to form at least one power conversion bridge arm;
at least one high-frequency capacitor 2, wherein the power conversion bridge arm is connected in parallel with the high-frequency capacitor 2 so as to realize low-loop inductance interconnection;
the insulating heat-conducting material, the insulating heat-conducting material are arranged on the surface of the wiring layer 8 in an attached mode, the insulating material can be an insulating heat-conducting carrier plate 3, an insulating heat-conducting coating, insulating heat-conducting liquid and the like, the insulating heat-conducting carrier plate 3 is used as a general description, and the insulating heat-conducting carrier plate comprises a heat-conducting upper surface and a heat-conducting lower surface which are opposite to each other;
the packaging body 4 at least covers the embedded circuit board 1 and the insulating heat-conducting carrier plate 3, the two ends of the embedded circuit board 1 extend out of the plastic package body, and the surface of the insulating heat-conducting carrier plate 3 is exposed. The package body 4 is not limited to plastic packaging or a pouring sealant package 10 which is cured into a solid state or a gel state (which is encapsulated by pouring sealant). The package body 4 is only marked in FIG. 2A, and the package body 4 can be added in the other embodiments according to the characteristics.

As shown in FIG. 2A, taking a vertical switching device and two semiconductor power devices 6 as an example, firstly, the semiconductor power device 6 is embedded in an embedded circuit board 1 through an embedded process, the upper surface and the lower surface are electroplated or electroplated after drilling, and power electrodes on the upper surface and the lower surface of the semiconductor power device 6 are led out to the surface layer of the embedded circuit board 1 in a large area, so that low-loop inductance interconnection and almost no loss of thermal interface are achieved. Since the leading-out path is very short (such as less than 0.2 mm), the area is large (close to the upper and lower surface areas of the semiconductor power device 6), and is usually a copper material, so that the leading-out path is extremely small and even small to almost negligible. Preferably, the area ratio of the overlapping projection area of the power electrode wiring of the semiconductor power device 6 led out from the surface of the embedded circuit board and the semiconductor power device 6 to the area of the semiconductor power device 6 is greater than 60%. After the electrodes are led out, the power loops of the two semiconductor power devices 6 are nearby connected with the high-frequency capacitor 2 through the surface wiring of the embedded circuit board 1, and low-loop inductance is achieved.

The current direction of the commutation loop is shown in FIG. 2B, the current direction of the commutation loop flows to the SW end through the semiconductor power device 6 on the left side, and then flows to the semiconductor power device 6 on the right side through the upper-down connecting hole of the embedded circuit board 1, then flows through the semiconductor power device 6 on the right side and then flows to the Vbus-. It should be noted that the dotted line part refers to being staggered with the solid line part in the vertical paper surface direction, and the dotted line part and the solid line part can be overlapped in the vertical direction through disposing on the different wiring layer. Due to the opposite direction of the current path, the loop inductance is reduced to a very low level.

As shown in FIG. 2A, the heat dissipation component 5 is attached to the upper surface and/or the lower surface of the insulating heat-conducting carrier plate 3, the electric connection path 7 comprises a metal via hole path (i.e., a high-density and high-thermal-conductivity conductive path or a low-thermal-resistance path), the embedded semiconductor power device 6 comprises two opposite device surfaces, the two surfaces of the device are respectively connected to the upper surface and the lower surface of the embedded circuit board 1 by means of metal via holes, and is connected with a wiring layer 8 formed by a large-area surface metal layer arranged on the upper surface and the lower surface; and the metal layer can have the functions of through-flow and heat conduction at the same time, and can also only have a heat conduction function, and is also referred to as a heat dissipation layer. In the embodiment, the metal via hole path can be a high-density and high-thermal-conductivity conductive path or only a low-thermal-resistance path with low thermal resistance characteristics. A heat dissipation component 5 is arranged between the metal layer on the surface of the embedded circuit board 1 and the external heat exchange environment, so as to efficiently dissipate heat generated by the semiconductor power device 6 into the environment. The heat dissipation component 5 is usually made of a metal material, and as shown in FIG. 2A, the heat conduction lower surface of the insulating heat-conducting carrier plate 3 is attached to the heat dissipation surface of the upper surface and/or the lower surface of the embedded circuit board 2, and the surface of the insulating heat-conducting carrier plate 3 can more cover graphical metal, that is, the insulating heat-conducting carrier plate 3 can be an insulating heat conduction dielectric layer of a heat conduction insulating carrier plate such as an aluminum oxide copper-clad ceramic substrate, an aluminum nitride copper-clad ceramic substrate, a silicon nitride copper-clad ceramic substrate, a Beryllium oxide ceramic copper-clad substrate, an insulated metal substrate. The metal layer covered on the surface of the insulating heat-conducting carrier plate 3 and the metal layer arranged on the surface of the embedded circuit board 1 can be electrically, thermally and mechanically connected through sintered material such as silver, copper and the like, and through high-thermal-conductivity materials such as solder, conductive silver paste and the like. As can be seen from FIG. 2A, when the heat generated by the semiconductor power device 6 is dissipated to the external environment through the upward or downward path, the heat only passes through one insulating heat conducting carrier plate 3. Due to the selected insulating material with relatively high thermal conductivity, but the thermal conductivity of the insulating material relative to the copper and other metals is relatively low. Therefore, the structure has an optimal heat dissipation effect.

In a preferred embodiment, the heat dissipation component 5 is a heat exchange fin, the heat exchange fin and the insulating heat-conducting carrier plate 3 are integrally formed, and heat exchange fins can also be arranged on the surface of the insulating heat-conducting carrier plate 3 through welding, sintering and the like. In addition, the fins not only can be independent, but also can be provided with a connecting sheet substrate.

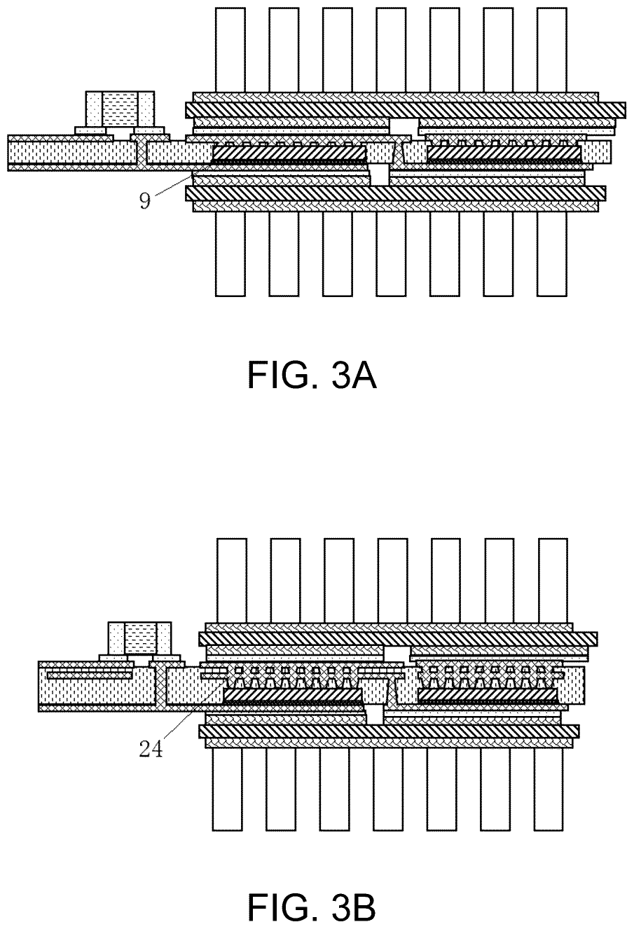

In some other embodiments, the electrical connection path 7 includes a bonding layer 9, the bonding layer 9 bonds one surface of the semiconductor power device 6 to the wiring layer 8, and the bonding layer 9 is a conductive material. As shown in FIG. 3A, since the vertical switching device is usually a three-port device, the two power electrodes are respectively arranged on the upper surface and the lower surface of the semiconductor power device 6 (such as the drain electrode of the MOSFET or the collector electrode of the IGBT), and the control electrode (in order to make the diagram simple and easy to understand, the drawings in the embodiments herein are not shown in detail), and one of the power electrodes is arranged on the same surface. Therefore, only one electrode is arranged on one surface of the semiconductor power device 6, and the surface of the semiconductor power device 6 can be directly bonded to the wiring layer 8 of the embedded circuit board 1 through a bonding material (such as silver, copper and other sintering materials, solder, conductive silver paste and the like) to form the bonding layer 9, so that a larger conductive and heat transfer area can be obtained through connection of the bonding layer 9 compared to the via hole, and lower electrical impedance and thermal impedance are obtained.

In a preferred embodiment, the electrical connection path 7 further comprises an inner-layer redistribution layer 24, as shown in FIG. 3B, the inner-layer redistribution layer 24 is horizontally disposed inside the embedded circuit board 1 to meet the requirements of complex wiring. Of course, the number of layers arranged on one side or two sides of the semiconductor power device 6 by the inner-layer redistribution layer 24 can be flexibly set according to actual conditions.

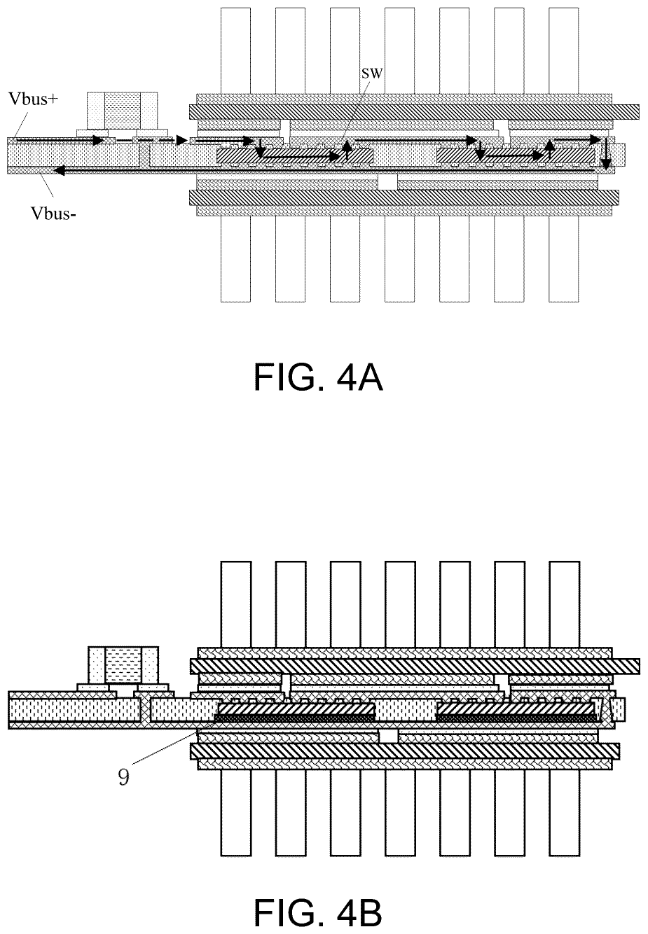

In a preferred embodiment, as shown in FIG. 4A, the electrodes of the planar switching device are led out on the same surface of the semiconductor power device 6, the surface of the semiconductor power device is the substrate of the semiconductor power device, after the electrode is led out, the power loops of the two semiconductor power devices 6 are connected with the high-frequency capacitor 2 nearby through wiring of the embedded circuit board 1, and low-loop inductance is achieved. The arrow line in the figure describes the current direction of the commutation loop, and it should be noted that the dashed arrow part in the direction perpendicular to paper surface is staggered with the solid line part. Because the current direction on the path is opposite, the loop inductance can be controlled to be extremely low. As shown in FIG. 4B, the non-functional surface of the planar switch device semiconductor power device 6 can pass through a bonding layer 9 (a conductive material such as silver, copper and other sintered materials, solder, conductive silver paste and the like; a non-conductive material such as ceramic slurry, glass slurry, high-thermal-conductivity epoxy adhesive, high-thermal-conductivity organic silica gel and the like) and directly bonding the surface to a wiring layer 8 of the embedded circuit board 1 to form a bonding layer 9.

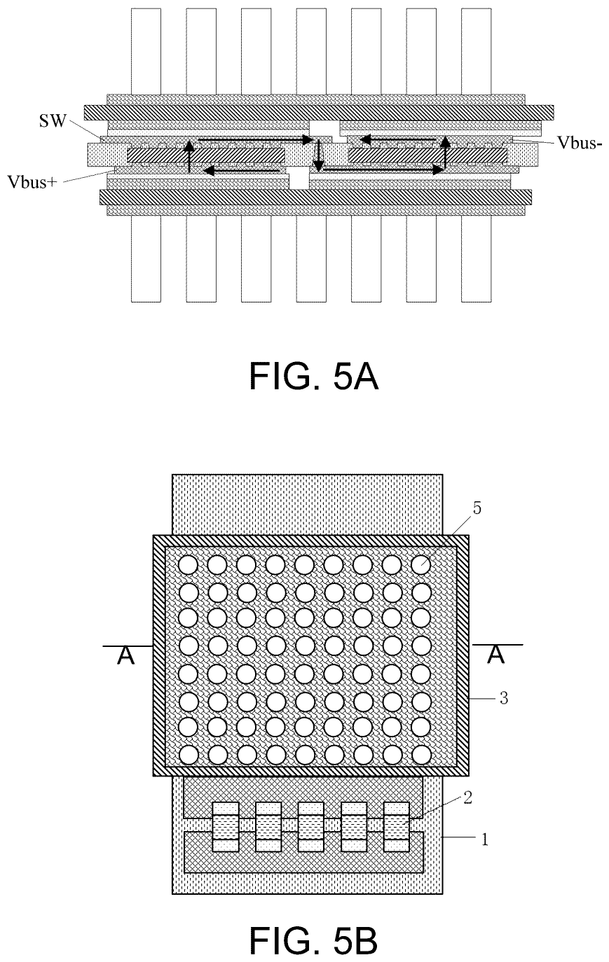

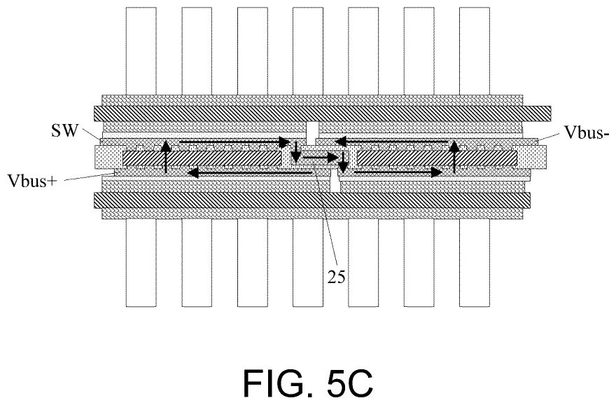

In some other embodiments, the connecting line directions of the two semiconductor power devices 6 are a first direction, and in the same horizontal plane, the direction perpendicular to the first direction is a second direction; and the high-frequency capacitor 2 is arranged in the second direction. As shown in FIG. 5A and FIG. 5B, the high-frequency capacitor 2 is arranged in an extension direction perpendicular to the cross-section A-A of the embedded circuit board 1, and Vbus+ and Vbus− can also be led out in the direction in a stacked mode. FIG. 5A shows the current direction of the A-A section circulation loop, it can be seen that the current in the direction of the paper surface is opposite, the current in the direction perpendicular to the paper surface is also opposite, and therefore the loop inductance is very small.

In a preferred embodiment, in the embedded circuit board 1, an interconnection metal layer 25 is arranged at the same height as the semiconductor power device 6, and the at least two semiconductor power devices 6 are connected in series through the interconnection metal layer 25; and projections of wiring layers connected with two electrodes of the high-frequency capacitor 2 are overlapped on the vertical section of the interconnection metal layer 25, as shown in FIG. 5C, the parasitic inductance of the loop can be further reduced.

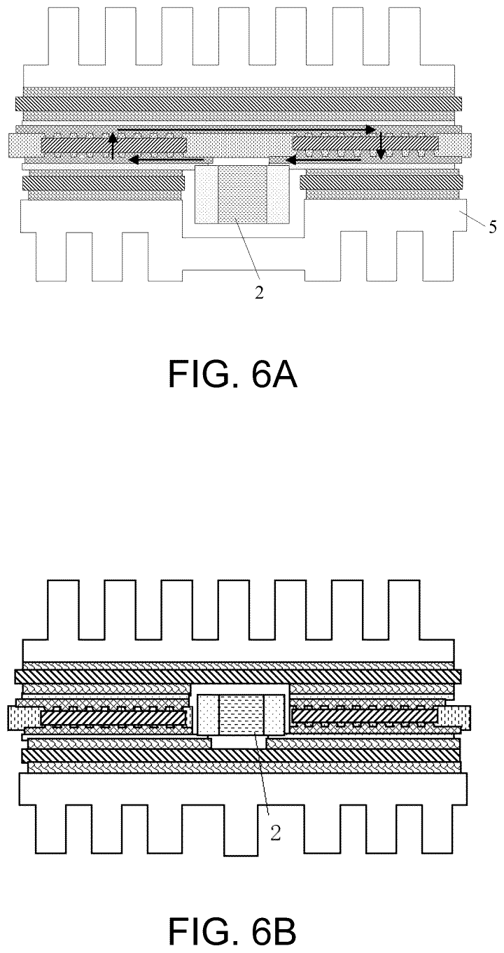

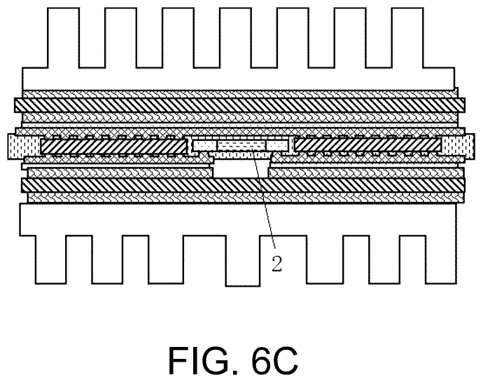

In some other embodiments, the high-frequency capacitor 2 is disposed on a surface of the embedded circuit board 1 and is located between two semiconductor power devices 6 of a power conversion bridge arm; and a space avoidance structure for accommodating the high-frequency capacitor 2 is arranged on the insulating heat-conducting carrier plate 3 and/or the heat dissipation component 5, as shown in FIG. 6A, the high-frequency capacitor 2 is arranged on the surface of the embedded circuit board 1 and located in the middle of the two semiconductor power devices 6, and it can be seen from the current trend of the power loop in the figure that the current directions of the upper layer and the lower layer are opposite, so that the loop inductance is extremely small. In order to avoid the high-frequency capacitor 2, holes need to be formed between the insulating heat-conducting carrier plates 3 on one side, and corresponding heat dissipation components 5 may also need to perform space avoidance.

In a preferred embodiment, the embedded circuit board 1 is provided with an opening structure, the opening structure is located between two semiconductor power devices 6 of a power conversion bridge arm, and the high-frequency capacitor 2 is arranged at the opening structure, as shown in FIG. 6B.

In a preferred embodiment, the high-frequency capacitor 2 is embedded in the embedded circuit board 1, and the high-frequency capacitor 2 is located between two semiconductor power devices 6 of a power conversion bridge arm, as shown in FIG. 6C.

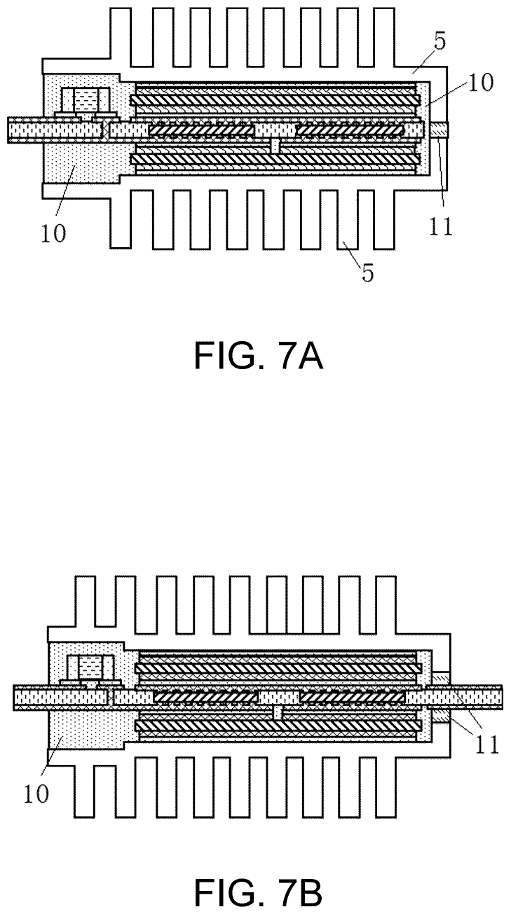

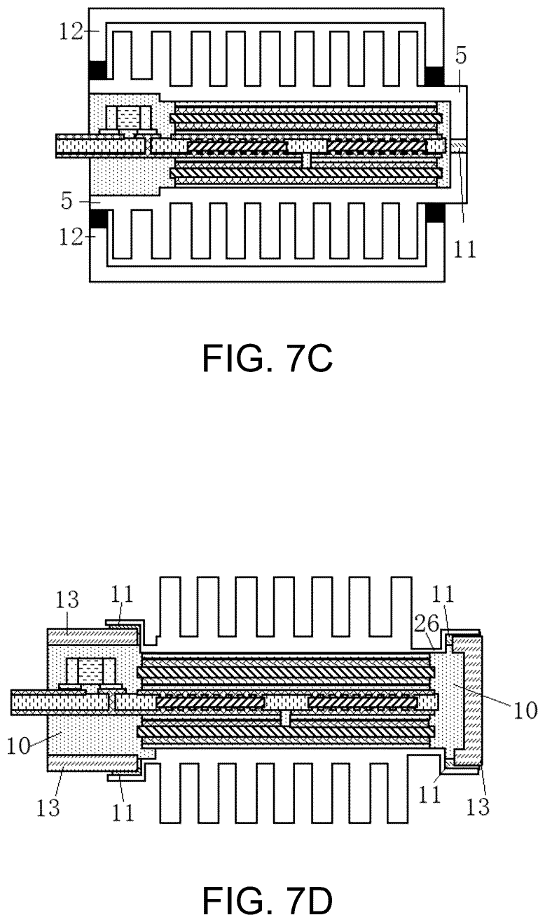

In other embodiments, the packaging body 4 is formed by packaging a pouring sealant package 10, the heat dissipation component 5 comprises an upper heat dissipation component and a lower heat dissipation component, and the upper heat dissipation component and the lower heat dissipation component are respectively located on the upper side and the lower side of the embedded circuit board 1; the upper heat dissipation component and the lower heat dissipation component are connected with one side of the embedded circuit board 1 in a sealed mode to form a cavity structure, the cavity structure is filled with liquid pouring sealant, and a pouring sealant package 10 is formed through curing. In order to reduce the creepage distance between the circuit board surface lines and between the surface lines of the insulating heat-conducting carrier plate 3, filling the areas with an insulating material is a very effective method, wherein the glue is filled with liquid, and the pouring sealant package 10 (such as liquid epoxy pouring sealant, organic silicon pouring sealant and the like) is formed through curing, which is one of the most common methods. As shown in FIG. 7A, firstly, the upper heat dissipation component and the lower heat dissipation component and the insulating heat-conducting carrier plate 3 are assembled by adopting silver, copper sintering materials, solder, silver paste and the like. A sealing member 11, such as a liquid sealant, is then provided in the middle of the upper and lower heat dissipation members. Certainly, the sealing interface can be closed through welding, such as fusion welding, friction stir welding and the like. Then, pouring sealant is poured into a cavity formed by closing the upper heat dissipation component and the lower heat dissipation component, and curing is carried out. In order to achieve a good filling effect, processes such as vacuum defoaming can be matched.

In a preferred embodiment, the embedded circuit board 1 extends out of the cavity structure in at least two directions, as shown in FIG. 7B, different from FIG. 7A, the embedded circuit board 1 extends out of the heat dissipation component 5 to form a closed space in two or more directions, so as to increase the convenience of input and output.

Further, a liquid cooling cover plate 12 is arranged outside the heat dissipation component 5, a sealing ring can be used for preventing leakage between the liquid cooling cover plate 12 and the heat dissipation component 5, and sealing can also be achieved through welding such as fusion welding, friction stir welding and the like, as shown in FIG. 7C.

In a preferred embodiment, the device further comprises a shell 13, one end of the shell 13 is open, an opening for containing the heat dissipation component 5 is formed in the middle of the shell 13, the shell 13 is hermetically connected with the heat dissipation component 5 to form a cavity structure, the cavity structure is filled with liquid pouring sealant, and the pouring sealant package 10 is formed through curing. As shown in FIG. 7D, an opening in one end of the shell 13 is used for exposing one end of the embedded circuit board 1 and opening the position of the upper and lower heat dissipation parts. The material of the shell 13 is not limited to metal, nonmetal and the like. Then, the upper heat dissipation component, the lower heat dissipation component and the insulating heat-conducting carrier plate 3 are assembled by adopting silver, copper sintering materials, solder, silver paste and the like. The upper heat dissipation part and the lower heat dissipation part and the shell 13 are closed through the sealant, and certainly, the sealing interface can be closed through welding, such as fusion welding, friction stir welding and the like. In this way, the processing surface is planar, and three-dimensional processing is avoided.

Further, in order to absorb the assembly tolerance, a thin-wall structure 26 can be arranged between the heat dissipation component 5 and the shell 13.

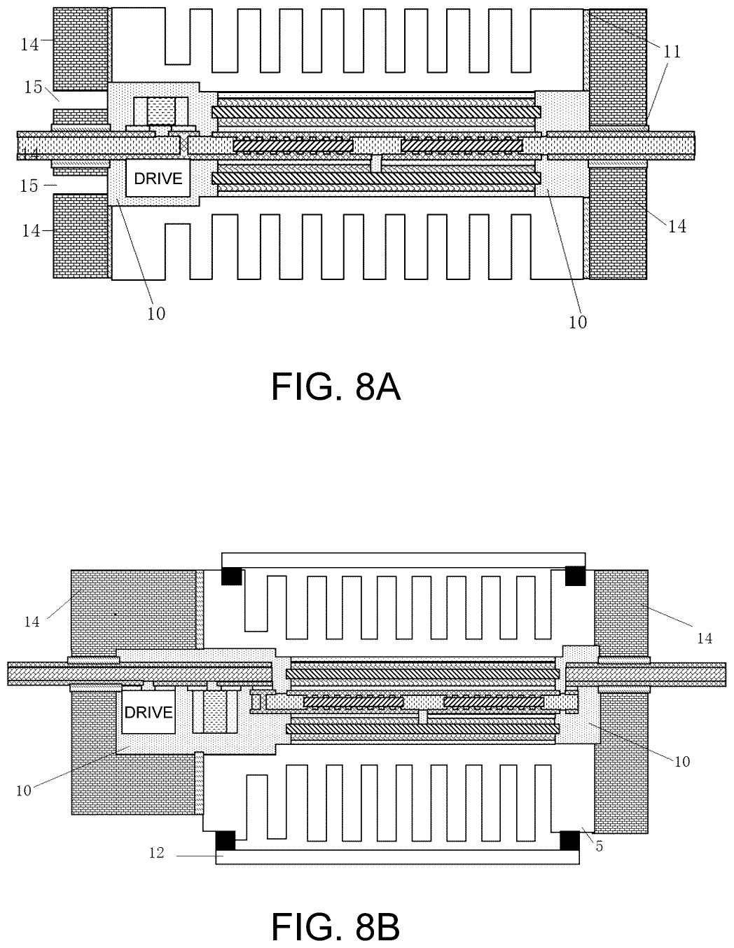

In some other embodiments, sealing baffles 14 are further arranged on the two sides of the heat dissipation component 5, a glue injection opening 15 is formed in one sealing baffle 14, the sealing baffle 14 is in sealed connection with the heat dissipation component 5 to form a cavity structure, the cavity structure is filled with liquid pouring sealant, and the pouring sealant package 10 is formed by curing, as shown in FIG. 8A, the sealing baffle 14 is made of a sealing material, such as liquid sealant and the like, and certainly, the sealing interface needing to be sealed can be closed through welding, such as fusion welding, friction stir welding and the like, and then pouring sealant is injected through the glue injection opening 15.

Furthermore, the sealing baffle 14 is a special-shaped sealing baffle 14, so that a larger cavity structure is formed by enveloping, as shown in FIG. 8B, a larger mainboard is conveniently adopted, and more functions, such as a driving element and the like, are integrated. Of course, the sealing baffle 14 can also be integrally formed with the heat dissipation component 5, that is, the heat dissipation component 5 is a shell of the module.

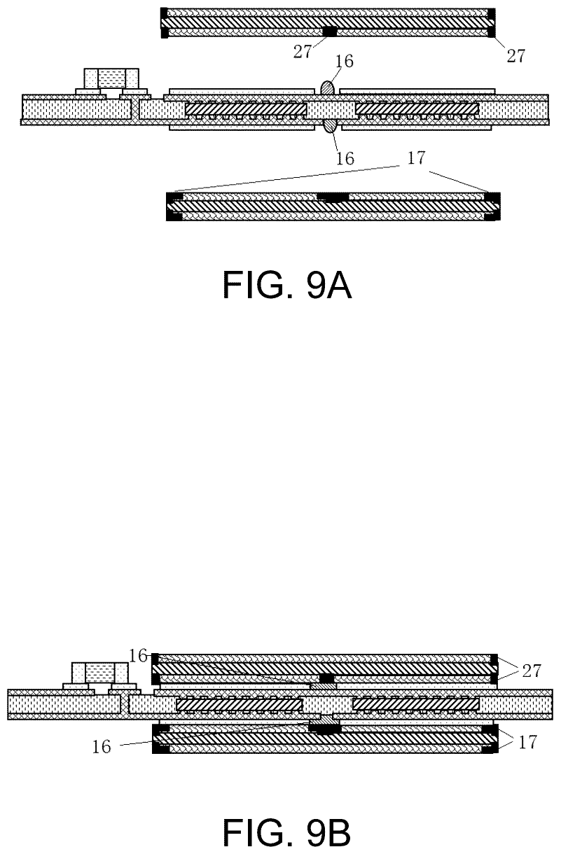

In other embodiments, the gap between the insulating heat-conducting carrier plate 3 and the wiring layer 8 is pre-filled with a dot-shaped insulating adhesive 16, and the side wall of the insulating heat-conducting carrier plate 3 is provided with a step-shaped structure 17. As shown in FIGS. 9A and 9B, firstly, gaps between the wiring layers of the insulating heat-conducting carrier plate 3 are filled in a manner of dispensing, compression molding and the like. In this way, the usage amount of subsequent adhesive materials can be effectively reduced, and the risk of mixing bubbles can be effectively reduced. The side wall of the peripheral circuit of the insulating heat-conducting carrier plate 3 can also be protected through the protective glue 27, so that the reliability of the insulating heat-conducting carrier plate 3 can be greatly improved. Furthermore, the shape of the wiring side wall of the insulating heat-conducting carrier plate 3 can be set to be a step-shaped structure 17, so that the reliability of the insulating heat-conducting carrier plate 3 can be further improved. Subsequently, the bonding material and the dot-shaped insulating adhesive 16 are arranged on the insulating heat-conducting carrier plate 3 or the embedded circuit board 1 according to needs. Then, the insulating heat-conducting carrier plate 3 and the embedded circuit board 1 are laminated and then assembled through a reflow soldering, sintering and other methods. It should be noted that the molding process of the bonding material and the curing process of the insulating adhesive are compatible. Such a combination of materials may be using solder paste for a bonding material, SMT red glue for insulating material, or Flow Underfill. When a silver or copper sintered material or conductive silver paste is used for a bonding material, a thermosetting adhesive and the like which the curing curve is similar is used for an insulating adhesive.

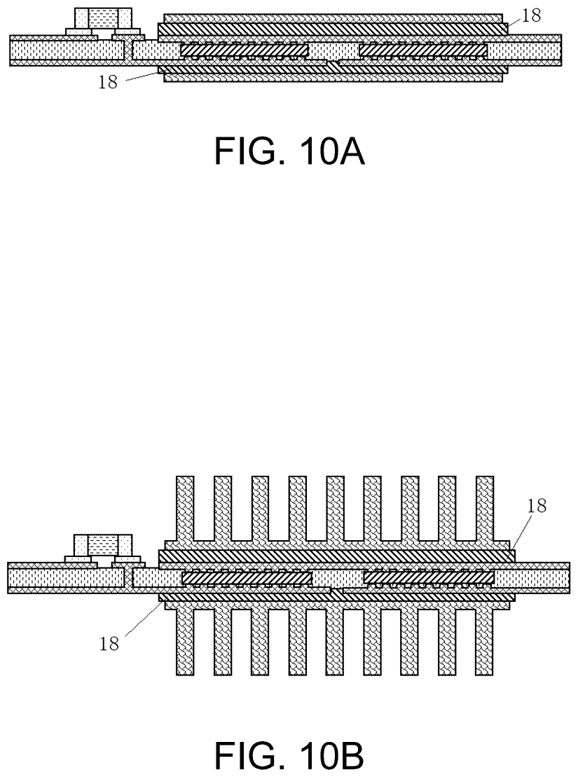

In some other embodiments, the insulating heat-conducting material is a high-thermal-conductivity insulating film 18, and the heat conductivity coefficient of the high-thermal-conductivity insulating film 18 is greater than 5 W/m·K. As shown in FIGS. 10A and 10B, the adopted high-thermal-conductivity insulating film 18 is a high-thermal-conductivity material filled with ceramic particles in an organic material, has certain deformation absorption capacity, and has high heat conductivity coefficient (>5 W/m·K) and high insulation capability. The copper foil (FIG. 10A) or the heat dissipation component 5 (FIG. 10B) with the heat exchange fins can be directly adhered to the outside of the high-thermal-conductivity insulating film 18.

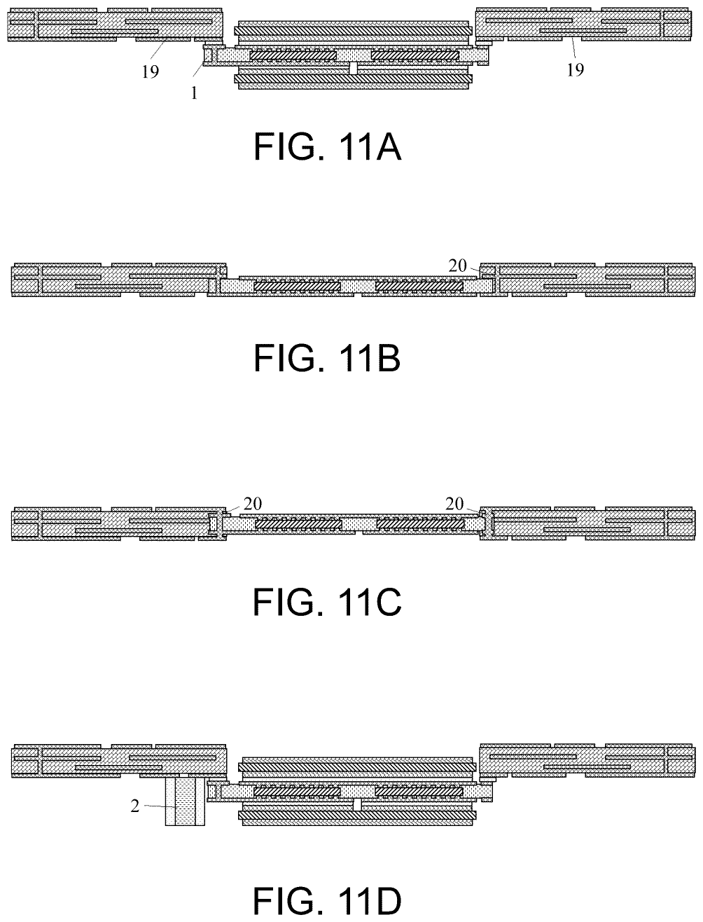

In some other embodiments, the module further comprises a system mainboard 19, and the embedded circuit board 1 is electrically connected with the system mainboard 19. Due to the fact that the precision requirement of the embedded circuit board 1 is high, the machining process is complex, and the cost is high. Therefore, compared with an economical method, the key part is processed by adopting an embedded technology, and the rest part adopts a traditional printed circuit board. Therefore, the connection mode of the system mainboard 19 and the embedded circuit board 1 needs to be considered. As shown in FIG. 11A, the embedded circuit board 1 is welded to the system main board 19 to connect the embedded circuit board 1 and the system main board 19.

Furthermore, the embedded circuit board 1 can be implanted in the system mainboard 19, as shown in FIGS. 11B and 11C, the embedded circuit board 1 is implanted into the system mainboard 19, and the system mainboard 19 and the embedded circuit board 1 are electrically connected through the through hole electric connection structure 20 (FIG. 11B, FIG. 11C) or the surface layer wiring layer 8 (FIG. 11B).

Furthermore, the high-frequency capacitor 2 can be arranged on the system mainboard 19, the high-frequency capacitor 2 is close to the embedded circuit board 1, as shown in FIG. 11D, the embedded circuit board 1 is welded to the system mainboard 19, and the high-frequency capacitor 2 is placed at the position, closest to the embedded circuit board 1, of the system mainboard 19.

The advantage of the embodiment is that the interconnection lead of the embedded circuit board 1 and the system mainboard 19 is very short. Even if the high-frequency capacitor 2 is placed on the system main board 19 as shown in FIG. 11D, a very small loop inductance is also provided. Compared with the fact that the high-frequency capacitor 2 is arranged on the embedded circuit board 1, the Loop inductance slightly rises, but is greatly superior to the existing scheme, the requirements of many scenes are met, the complexity of the embedded circuit board 1 is also reduced, and the yield and the compactness of the heat dissipation system are improved.

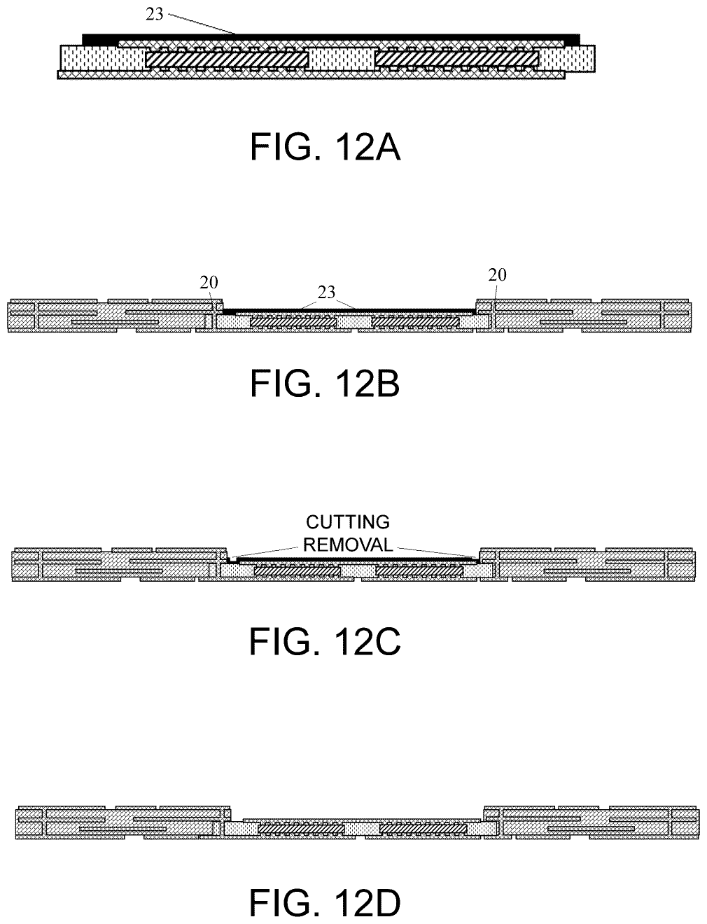

FIG. 12A to FIG. 12D show a manufacturing method of the module as shown in FIG. 11B. The method comprises the following steps:

S1: a temporary protective layer 23 is arranged on the upper surface of the embedded circuit board 1, as shown in FIG. 12A, due to the fact that the lower surface of the embedded circuit board 1 is flush with the surface of the system main board 19, the lower surface of the embedded circuit board 1 may not be attached to the temporary protective layer 23, and the pattern of the surface may not be made when the embedded circuit board 1 is manufactured;

S2: the embedded circuit board 1 is arranged in the system mainboard 19, and the surface of the embedded circuit board 1 which is not provided with the temporary protection layer 23 is flush with one surface of the system mainboard 19;

S3: the arrangement of the through hole electric connection structure 20 and the surface layer wiring layer is completed, as shown in FIG. 12B, it should be noted that the stacking of the system main board 19 can perform windowing processing on a prepreg (PP), a core board (Core) and the like located at the position of the embedded circuit board 1 according to actual conditions;

S4: cutting off the periphery of the embedded circuit board 1 needing to be exposed, exposing the temporary protective layer 23, and removing the periphery of the whole board as shown in FIG. 12C;

S5: removing the temporary protective layer 23, and forming a final structure as shown in FIG. 12D.

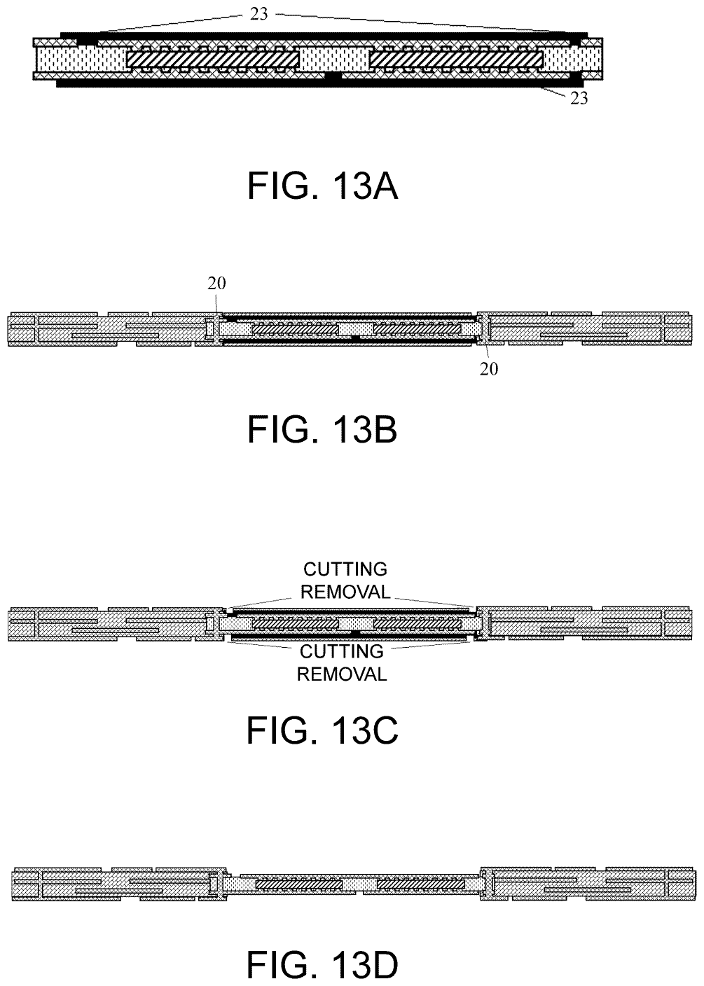

FIG. 13A to FIG. 13D show a manufacturing method of the module as shown in FIG. 11C. The method comprises the following steps:

S1: respectively arranging a temporary protective layer 23 on the upper surface and the lower surface of the embedded circuit board 1, as shown in FIG. 13A;

S2: arranging the embedded circuit board 1 in the system main board 19;

S3: the arrangement of the through hole electric connection structure 20 is completed, as shown in FIG. 13B, it should be noted that the stacking of the system main board 19 may need to perform windowing processing on a prepreg (PP), a core board (Core) and the like located at the position of the embedded circuit board 1 according to actual conditions.

S4: cutting off the periphery of the embedded circuit board 1 needing to be exposed, and exposing the temporary protection layer 23, as shown in FIG. 13C;

S5: removing the temporary protective layer 23 to form a final structure, as shown in FIG. 13D.

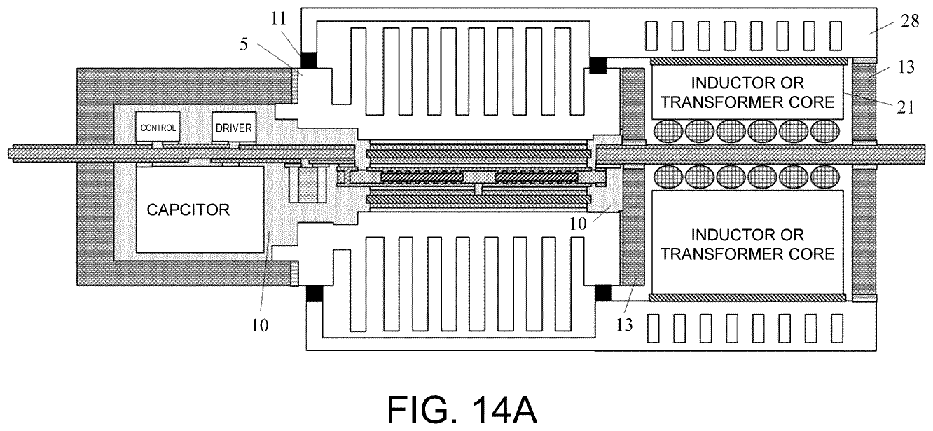

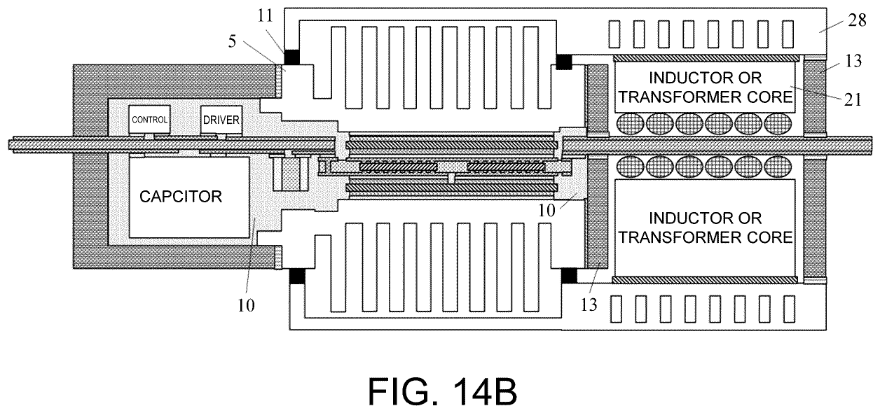

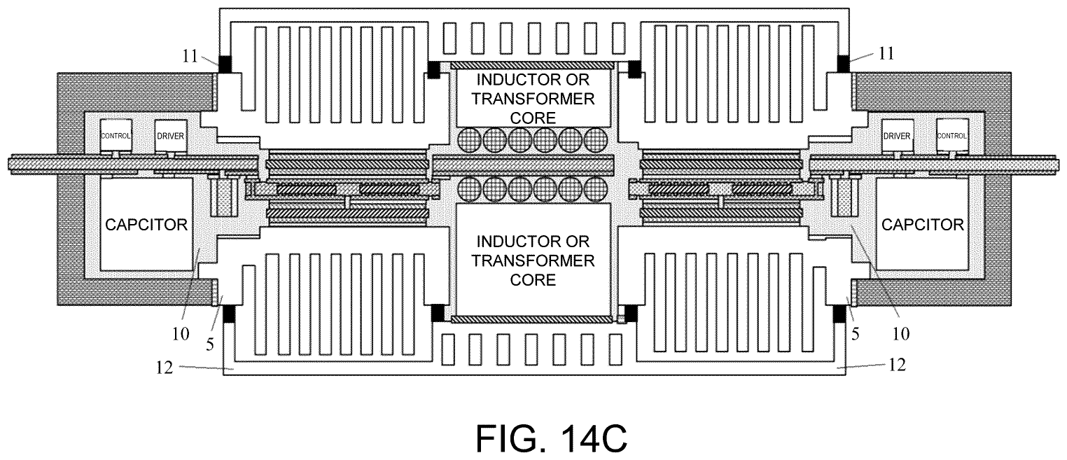

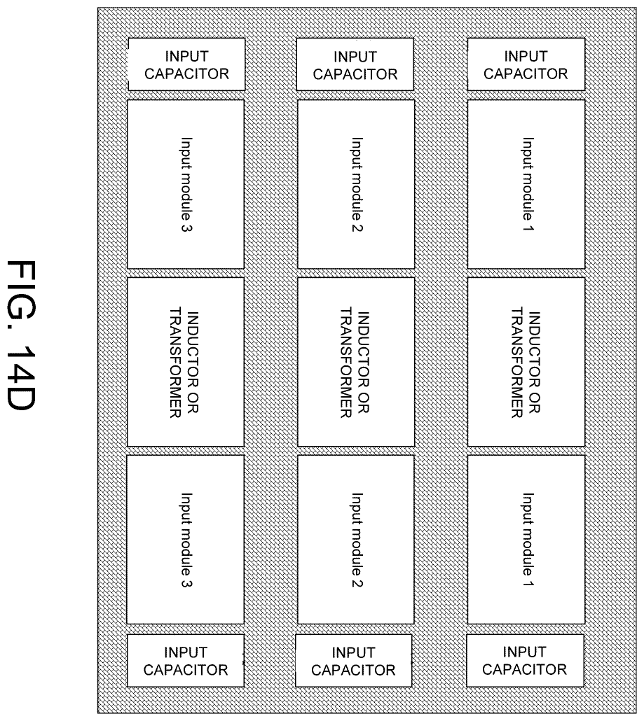

In some other embodiments, a liquid cooling cover plate 12 is arranged outside the heat dissipation component 5, a sealing piece 11 is arranged at the joint of the liquid cooling cover plate 12 and the heat dissipation component 5, the liquid cooling cover plate 12 extends out of the side edge of the heat dissipation component 5 to form a liquid flow channel 28, and a magnetic element 21 is attached to the inner side of the liquid flow channel 28; and the outer side of the liquid flow channel 28 seals the magnetic element 21 by arranging a sealing baffle 14; and a system mainboard 19 in the cavity structure is provided with one or more of a driving element, a low-frequency large-volume element, a control unit and a magnetic element 21. As shown in FIG. 14A, various functional components such as a controller and a low-frequency large-volume capacitor are integrated on the system mainboard 19, and a magnetic element 21, such as an inductor or a transformer, used by a switching power supply is further integrated. Moreover, the liquid cooling cover plate 12 can dissipate heat of the magnetic element 21. Furthermore, the inner of the liquid flow channel 28 and the position, corresponding to the magnetic element 21, is integrated the liquid cooling cover plate 12, so that the heat dissipation capacity of the liquid cooling cover plate 12 is further improved, and the used cooling water and the liquid used for heat dissipation of the semiconductor power device 6 are the same source, so that the cooling design is further simplified.

In a preferred embodiment, the sealing baffle 14 between the liquid flow channel 28 and the heat dissipation component 5 is removed, so that the liquid flow channel 28, the heat dissipation component 5 and the sealing baffle 14 form a larger cavity structure. As shown in FIG. 14B, the main difference with FIG. 14A is that the part with pouring sealant further comprises a part of the magnetic element 21, which is important for improving the withstand voltage of the part of the magnetic element 21, especially the withstand voltage of the primary side and secondary side of the transformer, and reducing the spatial distance between the terminals.

In a preferred embodiment, in the same cavity structure, the system mainboard 19 is provided with a plurality of embedded circuit boards 1, and the system mainboard 19 near each embedded circuit board 1 is provided with one or more of a driving element, a low-frequency large-volume element, a control unit and a magnetic element 21 to form a circuit unit. As shown in FIG. 14C, compared with FIG. 14B, the main difference is that the part with pouring sealant further comprises a plurality of embedded circuit boards 1, and more elements such as secondary side driving, control and capacitors are integrated, so that more complex circuit functions are realized. Further, a plurality of circuit units are integrated on a system mainboard 19, as shown in FIG. 14D, so that the modules shown in FIG. 12C are integrated on one system mainboard 19 to expand power.

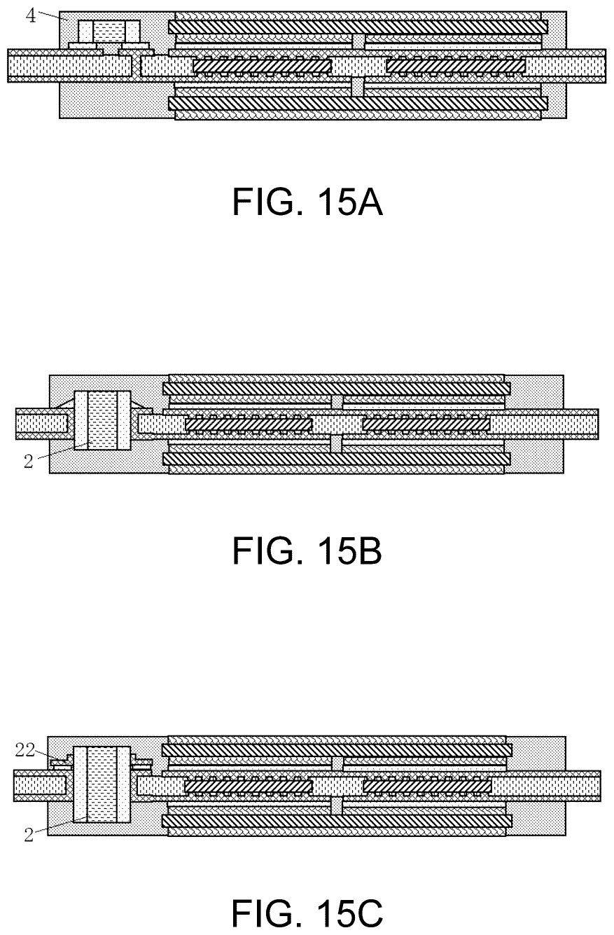

In some other embodiments, the packaging body 4 is formed by packaging a plastic packaging material, as shown in FIG. 15A, a plastic packaging mode of transfer molding is adopted, and tiny gaps can be better filled by means of injection molding pressure. Moreover, due to the fact that the strength of the plastic packaging material is high, the effect of reinforcing the structure can be achieved.

In a preferred embodiment, a vertically penetrating through opening is formed in the embedded circuit board 1, the high-frequency capacitor 2 is arranged in the through opening, as shown in FIG. 15B, a hole can be formed between the embedded circuit board 1 to assemble the high-frequency capacitor 2 with high thickness, and the terminal of the high-frequency capacitor 2 can be connected with the surface and the side wall of the embedded circuit board 1 through solder.

Further, as shown in FIG. 15C, the horizontal terminals 22 which are horizontally unfolded are arranged at two ends of the high-frequency capacitor 2. Due to enhance the structure of the plastic packaging material, so that the risk of cracking of the high-frequency capacitor 2 body and the connecting position can be effectively avoided which is easily caused by installation of the penetrating high-frequency capacitor 2.

The embodiment of the application further discloses an embedded integrated device unit for the high-heat-dissipation high-frequency power module. The embedded integrated device unit comprises an embedded circuit board 1, at least two semiconductor power devices 6, at least one high-frequency capacitor 2 and an insulating heat-conducting carrier plate 3.

The embedded circuit board 1 comprises an upper surface and a lower surface which are opposite to each other, an inner layer, at least one electrical connection channel 7 and at least one high-density high-thermal-conductivity conductive path, wherein the upper surface or the lower surface comprises at least one wiring layer 8; the at least two semiconductor power devices 6 are horizontally arranged on the inner layer of the embedded circuit board 1, each semiconductor power device 6 comprises one power electrode, the power electrodes of the at least two semiconductor power devices 6 are electrically connected with the wiring layer 8 through the electrical connection channels 7, and the power electrodes (through the wiring layer 8) of the at least two semiconductor power devices 6 are connected in series to form at least one power conversion bridge arm; the semiconductor power device 6 comprises two opposite device surfaces, the surface of the at least one device is connected with the wiring layer through a high-density and high-thermal-conductivity conductive path, and the wiring layer connected with the high-density and high-thermal-conductivity conductive path can serve as a heat dissipation surface and is attached to the insulating and heat-conducting carrier plate 3; the embedded circuit board comprises at least two direct-current power electrodes, and the two ends of the high-frequency capacitor are electrically connected with the two direct-current power electrodes respectively, so that the power conversion bridge arm is connected with the high-frequency capacitor in parallel so as to realize low-loop electrical interconnection.

In a preferred embodiment, the embedded integrated device unit comprises an upper heat dissipation surface and a lower heat dissipation surface which are opposite to each other, the surface of the device of each semiconductor power device 6 is electrically connected with the wiring layer 8 on the upper surface and the lower surface of the embedded circuit board 1 through high-density and high-thermal-conductivity electrical connection channels, the wiring layer 8 is an upper heat dissipation surface and a lower heat dissipation surface of the semiconductor power device 6, and the at least two insulating heat-conducting carrier plates 3 are respectively attached to the upper heat dissipation surface and the lower heat dissipation surface to realize double-sided heat dissipation.

In a preferred embodiment, the semiconductor power device 6 is a vertical switch device, and the device surface corresponding to the upper heat dissipation surface or the lower heat dissipation surface of the embedded integrated device unit is the drain electrode of the MOSFET or the collector of the IGBT; in other embodiments, the semiconductor power device 6 may also be a planar switch device, and then the surface of the semiconductor power device 3 corresponding to the upper heat dissipation surface or the lower heat dissipation surface of the embedded integrated device unit is the substrate of the semiconductor power device.

The embodiment of the application further discloses a double-sided heat dissipation power converter. The double-sided heat dissipation power converter comprises a double-sided heat dissipation packaging integrated device unit, at least two insulating heat conduction substrates, at least one large-area multi-layer circuit board, at least one high-frequency capacitor, at least one magnetic assembly, at least one driving element and two heat dissipation components; the double-sided heat dissipation packaging integrated device unit comprises at least two semiconductor power devices 6, the upper surface and the low surface of the device unit and the at least two low-thermal-resistance channels, each semiconductor power device 6 comprises a power electrode and two opposite device surfaces, a power electrode of each semiconductor power device 6 is connected in series to form a bridge arm, and the surfaces of the two devices of each semiconductor power device 6 pass through the upper surface of the corresponding low-thermal-resistance channel connector unit and the lower surface of the device unit; and the at least two insulating heat-conducting substrates are respectively arranged on the upper surface of the device unit and the lower surface of the device unit; the large-area multilayer circuit board comprises at least one opening, and the opening is used for mounting the double-sided heat dissipation packaging integrated device unit; at least one high-frequency capacitor is arranged adjacent to the bridge arm, the bridge arm comprises at least two direct-current electrodes and a bridge arm middle point, and the two ends of the high-frequency capacitor are electrically connected with the at least two direct-current electrodes respectively to form a low-loop power channel; the at least one driving element is used for driving the semiconductor power device at high frequency; the at least one magnetic element is connected with the midpoint of the bridge arm, and the bridge arm and the magnetic element together realize a high-frequency energy conversion function; and the two heat dissipation components are arranged on the outer side surfaces of the insulating heat-conducting substrate and the magnetic element respectively.

The embodiment disclosed by the application has excellent double-sided heat dissipation capability, but even if the technical features disclosed by the application are applied to a single-sided heat dissipation device, good heat dissipation capability can be realized, and the high-frequency electrical capability can be considered.

What is claimed is:

1. A high-heat-dissipation high-frequency power module, comprising:
an embedded circuit board, at least two semiconductor power devices, at least one high-frequency capacitor, and an insulating heat-conducting carrier plate;
wherein the embedded circuit board comprises an upper surface and a lower surface which are opposite to each other, an inner layer, at least one electrical connection path, and at least one high-density and high-thermal-conductivity conductive path, wherein the upper surface comprises a first wiring layer, and the lower surface comprises a second wiring layer;
the at least two semiconductor power devices are arranged in the embedded circuit board, each of the at least two semiconductor power devices comprises a power electrode, power electrodes of the at least two semiconductor devices are electrically connected with the wiring layer through the electrical connection paths, and power electrodes of the at least two semiconductor devices are electrically connected to form at least one power conversion bridge arm in the high-heat-dissipation high frequency power module;
each of the at least two semiconductor power devices comprises two opposite device surfaces, at least one of the two opposite device surfaces is connected with the wiring layer through the high-density high-thermal-conductivity conductive path, and the wiring layer connected with the high-density high-thermal-conductivity conductive path serves as a heat dissipation surface;
the at least one high-frequency capacitor is arranged adjacent to the power conversion bridge arm and is electrically connected with the power conversion bridge arm in parallel so as to realize low-loop electrical interconnection;
the insulating heat-conducting carrier plate comprises a heat-conducting upper surface and a heat-conducting lower surface which are opposite to each other, and the heat-conducting lower surface is attached to the heat-dissipating surface;
the insulating heat-conduction carrier plate covers an area corresponding with the power conversion bridge arm;
the connecting direction of at least two semiconductor power devices is a first direction, and the direction perpendicular to the first direction is a second direction in the same horizontal plane;
the at least one high-frequency capacitor is disposed in a second direction;
wherein the at least two semiconductor power devices, the first wiring layer and the second wiring layer form a conductive path in a “∞” shape on the cross section in the first direction; the current flowing in the conductive path from a Vbus+ terminal to a Vbus− terminal; the Vbus+ terminal and the Vbus− terminal are led out in the second direction in stacked mode, so as to realize a low-loop electrical interconnection.

2. The high-heat-dissipation high-frequency power module of claim 1, further comprising a packaging body and a heat dissipation component,
wherein the packaging body at least covers a part of the embedded circuit board and the insulating heat-conducting carrier plate, at least one end of the embedded circuit board directly or indirectly extends to the outside of the projection of the insulating heat-conducting carrier plate on the embedded circuit board, and the heat-conducting upper surface of the insulating heat-conducting carrier plate is exposed;
wherein the heat dissipation component is arranged on the surface of the insulating heat-conducting carrier plate in an attached mode.

3. The high-heat-dissipation high-frequency power module of claim 2, wherein the package body is formed by encapsulating a pouring sealant;
the heat dissipation component comprises an upper heat dissipation component and a lower heat dissipation component, and the upper heat dissipation component and the lower heat dissipation component are located on the upper side and the lower side of the embedded circuit board respectively; The upper heat dissipation component and the lower heat dissipation component are hermetically connected to one side of the embedded circuit board to form a cavity structure, and the cavity structure is filled with liquid pouring sealant.

4. The high-heat-dissipation high-frequency power module of claim 2, wherein the packaging body is formed by a plastic packaging material;
the gap between the insulating heat-conducting carrier plate and the wiring layer is pre-filled with a dispensing adhesive, and the side wall of the insulating heat-conducting carrier plate is provided with a step-shaped structure.

5. The high-heat-dissipation high-frequency power module of claim 1, further comprising a system mainboard,
wherein the embedded circuit board is implanted in the system mainboard and is connected with the system mainboard;
one side of the embedded circuit board is flush with one side of the system mainboard, and the embedded circuit board and the system mainboard are electrically connected through a through-hole electrical connection structure and/or a surface wiring layer.

6. The high-heat-dissipation high-frequency power module of claim 1, wherein the at least two semiconductor power devices in one power conversion bridge arm are arranged in a same embedded circuit board.

7. A high-heat-dissipation high-frequency power module, comprising:
an embedded circuit board, at least two semiconductor power devices, at least one high-frequency capacitor, and an insulating heat-conducting carrier plate;
the embedded circuit board comprises an upper surface and a lower surface which are opposite to each other, an inner layer, at least one electrical connection path and at least one high-density and high-thermal-conductivity conductive path, wherein the upper surface comprises a first wiring layer and the lower surface comprises a second wiring layer;
the at least two semiconductor power devices are arranged in the embedded circuit board, each of the at least two semiconductor power devices comprises a power electrode, power electrodes of the at least two semiconductor devices are electrically connected with the wiring layer through the electrical connection paths, and power electrodes of the at least two semiconductor devices are electrically connected to form at least one power conversion bridge arm in the high-heat-dissipation high frequency power module;
each of the at least two the semiconductor power devices comprises two opposite device surfaces, at least one of the two opposite device surfaces is connected with the wiring layer through the high-density high-thermal-conductivity conductive path, and the wiring layer connected with the high-density high-thermal-conductivity conductive path serves as a heat dissipation surface;
the at least one high-frequency capacitor is arranged adjacent to the power conversion bridge arm and is electrically connected with the power conversion bridge arm in parallel so as to realize low-loop electrical interconnection;
the insulating heat-conducting carrier plate comprises a heat-conducting upper surface and a heat-conducting lower surface which are opposite to each other, and the heat-conducting lower surface is attached to the heat-dissipating surface;
the insulating heat-conducting carrier plate covers an area corresponding to the power conversion bridge arm;
the at least one high frequency capacitor is arranged in an area not covered by the insulating heat-conducting carrier plate.

8. The high-heat-dissipation high-frequency power module of claim 7, wherein the at least one high frequency capacitor is arranged along a side of the heat-conducting carrier plate in a row.

9. The high-heat-dissipation high-frequency power module of claim 7, further comprising a packaging body and a heat dissipation component,
wherein the packaging body at least covers a part of the embedded circuit board and the insulating heat-conducting carrier plate, at least one end of the embedded circuit board directly or indirectly extends to the outside of the projection of the insulating heat-conducting carrier plate on the embedded circuit board, and the heat-conducting upper surface of the insulating heat-conducting carrier plate is exposed;
wherein the heat dissipation component is arranged on the surface of the insulating heat-conducting carrier plate in an attached mode.

10. The high-heat-dissipation high-frequency power module of claim 9, wherein the heat dissipation component comprises an upper heat dissipation component and a lower heat dissipation component, and the upper heat dissipation component and the lower heat dissipation component are located on the upper side and the lower side of the embedded circuit board, respectively.

11. The high-heat-dissipation high-frequency power module of claim 10, wherein the package body is formed by encapsulating a pouring sealant;
the upper heat dissipation component and the lower heat dissipation component are hermetically connected to one side of the embedded circuit board to form a cavity structure, and the cavity structure is filled with liquid pouring sealant, and the liquid pouring sealant is cured in the cavity.

12. The high-heat-dissipation high-frequency power module of claim 11, wherein the embedded circuit board extends out of the cavity structure in at least two directions.

13. The high-heat-dissipation high-frequency power module of claim 11, further comprising a liquid cooling cover plate and a sealing piece,
wherein the liquid cooling cover plate and the sealing piece are arranged outside the heat dissipation component, and the sealing piece is arranged at the joint of the liquid cooling cover plate and the heat dissipation component.

14. The high-heat-dissipation high-frequency power module of claim 11, further comprising a shell,
wherein one end of the shell is open, the other end of the shell is closed, an opening for containing a heat dissipation component is formed in the middle of the shell, the shell and the heat dissipation component are connected in a sealed mode to form a cavity structure, and the cavity structure is filled with liquid pouring sealant.

15. The high-heat-dissipation high-frequency power module of claim 14, further comprising a thin-wall structure,
wherein the thin-wall structure is arranged between the shell and the heat dissipation component, and the thin-wall structure is used for compensating for assembly tolerance.

16. The high-heat-dissipation high-frequency power module of claim 11, further comprising a sealing baffle,
wherein the sealing baffle is arranged on two sides of the heat dissipation component, a glue injection opening is formed in one sealing baffle, the sealing baffle and the heat dissipation component are connected in a sealed mode to form a cavity structure, and the cavity structure is filled with liquid pouring sealant.

17. The high-heat-dissipation high-frequency power module of claim 16, wherein the sealing baffle is a special-shaped baffle, and a larger cavity structure is formed by enveloping.

18. The high-heat-dissipation high-frequency power module of claim 7, wherein the packaging body is formed by packaging a plastic packaging material;
wherein a gap between the insulating heat-conducting carrier plate and the wiring layer is pre-filled with a dispensing adhesive, and the side wall of the insulating heat-conducting carrier plate is provided with a step-shaped structure.

19. The high-heat-dissipation high-frequency power module of claim 7, further comprising a system mainboard, wherein the embedded circuit board is electrically connected with the system mainboard.

20. The high-heat-dissipation high-frequency power module of claim 19, wherein the embedded circuit board is implanted to or is welded on a system mainboard; one side of the embedded circuit board is flush with one side of the system mainboard, and the embedded circuit board and the system mainboard are electrically connected through a through-hole electrical connection structure and/or a surface wiring layer.

21. The high-heat-dissipation high-frequency power module of claim 20, wherein the at least one high-frequency capacitor is arranged on a system mainboard, and the at least one high-frequency capacitor is close to the embedded circuit board;
wherein the high-heat-dissipation high-frequency power module further comprises a heat dissipation component, the heat dissipation component is attached to the heat conduction upper surface of the insulating heat-conducting carrier plate, sealing baffles are further arranged on two sides of the heat dissipation component, the sealing baffles and the heat dissipation component are connected in a sealed mode to form a cavity structure, and the cavity structure is filled with liquid pouring sealant.

22. The high-heat-dissipation high-frequency power module of claim 21, wherein a liquid cooling cover plate is arranged outside the heat dissipation component, and a sealing piece is arranged at the joint of the liquid cooling cover plate and the heat dissipation component.

23. The high-heat-dissipation high-frequency power module of claim 22, wherein the liquid cooling cover plate extends out of the side edge of the heat dissipation component to form a liquid flow channel, and a magnetic element is attached to an inner side of the liquid flow channel;
wherein an outer side of the liquid flow channel seals the magnetic element by providing a sealing baffle.

24. The high-heat-dissipation high-frequency power module of claim 23, wherein the sealing baffle between the liquid flow channel and the heat dissipation component is removed, so that the liquid flow channel, the heat dissipation component, and the sealing baffle form a cavity structure.

25. The high-heat-dissipation high-frequency power module of claim 21, wherein one or more of a driving element, a low-frequency large-size element, a control unit and a magnetic element are arranged on the system mainboard in the cavity structure.

26. The high-heat-dissipation high-frequency power module of claim 24, wherein in the same cavity structure, a plurality of embedded circuit boards are arranged on the system mainboard, and one or more of a driving element, a low-frequency large-size element, a control unit and a magnetic element are arranged on the system mainboard near each of the plurality of embedded circuit board to form a circuit unit; and the plurality of circuit units are integrated on a client mainboard.

27. The high-heat-dissipation high-frequency power module of claim 7, wherein a vertically penetrating through-opening is formed in the embedded circuit board, and the at least one high-frequency capacitor is arranged in the through-opening.

28. The high-heat-dissipation high-frequency power module of claim 7, wherein the at least two semiconductor power devices in one power conversion bridge arm are arranged in a same embedded circuit board.

29. A manufacturing method of the high-heat-dissipation high-frequency power module of claim 20, wherein the manufacturing method comprises the following steps:
S1: arranging a temporary protection layer on one surface of an embedded circuit board;
S2: arranging the embedded circuit board in the system mainboard, wherein a surface of the embedded circuit board which is not provided with the temporary protection layer is flush with one surface of the system mainboard;
S3: completing an arrangement of the through-hole electrical connection structure and the surface wiring layer;
S4: cutting off a periphery of the embedded circuit board needing to be exposed, and exposing the temporary protection layer;
S5: removing the temporary protective layer.

30. A manufacturing method of the high-heat-dissipation high-frequency power module of claim 20, wherein the manufacturing method comprises the following steps:
S1: respectively arranging a temporary protection layer on the upper surface and the lower surface of the embedded circuit board;
S2: arranging the embedded circuit board in the system mainboard;
S3: completing an arrangement of the through-hole electrical connection structure;
S4: cutting off the periphery of the embedded circuit board needing to be exposed, and exposing the temporary protection layer;
S5: removing the temporary protective layer.

31. A high-heat-dissipation high-frequency power module, comprising:
an embedded circuit board, at least two semiconductor power devices, at least one high-frequency capacitor, an insulating heat-conducting carrier plate, and a double-side-heat-dissipation half-sealed heat dissipation cover;
the embedded circuit board comprises an upper surface and a lower surface which are opposite to each other, an inner layer, at least one electrical connection path and at least one high-density and high-thermal-conductivity conductive path, wherein the upper surface comprises a first wiring layer and the lower surface comprises a second wiring layer;
the at least two semiconductor power devices are arranged in the embedded circuit board, each semiconductor power device comprises a power electrode, power electrodes of the at least two semiconductor devices are electrically connected with the wiring layer through the electrical connection paths, and power electrodes of the at least two semiconductor devices are electrically connected to form at least one power conversion bridge arm in the high-heat-dissipation high frequency power module;
each of the at least two semiconductor power devices comprises two opposite device surfaces, at least one of the two opposite device surfaces is connected with the wiring layer through the high-density high-thermal-conductivity conductive path, and the wiring layer connected with the high-density high-thermal-conductivity conductive path serves as a heat dissipation surface;
the at least one high-frequency capacitor is arranged adjacent to the power conversion bridge arm and is electrically connected with the power conversion bridge arm in parallel so as to realize a low-loop electrical interconnection;
the insulating heat-conducting carrier plate comprises a heat-conducting upper surface and a heat-conducting lower surface which are opposite to each other, and the heat-conducting lower surface is attached to the heat-dissipating surface; the insulating heat-conducting carrier plate covers an area corresponding to the power conversion bridge arm;
the double-side-heat-dissipation half-sealed heat dissipation cover comprises an upper heat dissipation component and a lower heat dissipation component, the upper heat dissipation component and the lower heat dissipation component are arranged on the upper side or the lower side of the at least one embedded circuit board, respectively;
the upper heat dissipation component and the lower heat dissipation component are hermetically connected to one side of the embedded circuit board to form a cavity structure, and the cavity structure is filled with a liquid pouring sealant.

32. The high-heat-dissipation high-frequency power module of claim 31, wherein a connecting direction of at least two semiconductor power devices is a first direction, and the direction perpendicular to the first direction is a second direction in the same horizontal plane;
wherein the at least one high-frequency capacitor is disposed in a second direction.

33. The high-heat-dissipation high-frequency power module of claim 32, wherein the embedded circuit board extends out of the cavity structure in at least two directions.

34. The high-heat-dissipation high-frequency power module of claim 31, further comprising a liquid cooling cover plate and a sealing piece,
wherein the liquid cooling cover plate and the sealing piece are arranged outside the heat dissipation component, and the sealing piece is arranged at the joint of the liquid cooling cover plate and the heat dissipation component.

35. The high-heat-dissipation high-frequency power module of claim 31, further comprising a shell,
wherein one end of the shell is open, the other end of the shell is closed, an opening for containing a heat dissipation component is formed in the middle of the shell, the shell and the heat dissipation component are connected in a sealed mode to form a cavity structure, and the cavity structure is filled with liquid pouring sealant.

36. The high-heat-dissipation high-frequency power module of claim 35, further comprising a thin-wall structure,
the thin-wall structure is arranged between the shell and the heat dissipation component, and the thin-wall structure is used for compensating for assembly tolerance.

37. The high-heat-dissipation high-frequency power module of claim 31, further comprising a sealing baffle,
wherein the sealing baffle is arranged on two sides of the heat dissipation component, a glue injection opening is formed in one sealing baffle, the sealing baffle and the heat dissipation component are connected in a sealed mode to form a cavity structure, and the cavity structure is filled with liquid pouring sealant.

38. The high-heat-dissipation high-frequency power module of claim 37, wherein the sealing baffle is a special-shaped baffle, and a larger cavity structure is formed by enveloping.

39. The high-heat-dissipation high-frequency power module of claim 31, further comprising at least two insulating heat-conducting carrier plate,
wherein the at least two insulating heat-conducting carrier plates are respectively attached to the upper heat dissipation surface and the lower heat dissipation surface.

40. The high-heat-dissipation high-frequency power module of claim 31, wherein the at least two semiconductor power devices in one power conversion bridge arm are arranged in a same embedded circuit board.
